(19) United States
(12) Patent Application Publication
(10) Pub. No.: US 2025/0393323 A1
(43) Pub. Date: Dec. 25, 2025

(54) IMAGE SENSOR AND METHOD OF MANUFACTURING THE SAME

(71) Applicant: SAMSUNG ELECTRONICS CO., LTD., Suwon-si (KR)

(72) Inventors: Jinseong PARK, Suwon-si (KR); Chungho SONG, Suwon-si (KR); Jamin LEE, Suwon-si (KR); Min-Jun CHOI, Suwon-si (KR); Woo Jun CHOI, Suwon-si (KR)

(73) Assignee: SAMSUNG ELECTRONICS CO., LTD., Suwon-si (KR)

(21) Appl. No.: 19/219,205

(22) Filed: May 27, 2025

(30) Foreign Application Priority Data
Jun. 25, 2024 (KR) 10-2024-0082463

(51) Int. Cl. H10F 39/00

(52) U.S. Cl. CPC H10F 39/8063; H10F 39/014

(57) ABSTRACT

An image sensor is provided. The image sensor includes: photodiodes provided in a pixel array region; a peripheral region provided on at least one side of the pixel array region; and a nanostructure layer provided on the pixel array region and the peripheral region. The nanostructure layer includes: metamicrolenses on the pixel array region, wherein the metamicrolenses are configured to collect light incident on the pixel array region; and a dummy nanopattern on the peripheral region.

### CROSS-REFERENCE TO RELATED APPLICATION

This application claims priority to Korean Patent Application No. 10-2024-0082463, filed on Jun. 25, 2024, in the Korean Intellectual Property Office, the disclosure of which is incorporated by reference herein in its entirety.

### BACKGROUND

The present disclosure relates to an image sensor and a method of manufacturing the same.

An image sensor is a semiconductor-based sensor employed in optical sensors or imaging modules to convert optical images into electrical signals. The image sensor includes a pixel array including a plurality of pixels.

The image sensor may be manufactured using various materials, and the various materials have different coefficients of thermal expansion. Therefore, stress-induced cracking often occurs due to a difference between coefficients of thermal expansion during an image sensor manufacturing process or a post-manufacturing evaluation process.

### SUMMARY

One or more example embodiments provide an image sensor with reduced a stress difference within the image sensor, and a method of manufacturing the same.

According to an aspect of an example embodiment, an image sensor includes: photodiodes provided in a pixel array region; a peripheral region provided on at least one side of the pixel array region; and a nanostructure layer provided on the pixel array region and the peripheral region. The nanostructure layer includes: metamicrolenses on the pixel array region, wherein the metamicrolenses are configured to collect light incident on the pixel array region; and a dummy nanopattern on the peripheral region.

According to another aspect of an example embodiment, a method of manufacturing an image sensor includes: providing a substrate with a pixel array region and a peripheral region; forming an etch-stop layer on the pixel array region and the peripheral region; forming an initial nanostructure layer comprising a material having a first refractive index on the pixel array region and the peripheral region; patterning the initial nanostructure layer to form a plurality of holes; depositing a material having a second refractive index, different from the first refractive index, in the plurality of holes to form nanoposts, forming metamicrolenses using the nanoposts on the pixel array region; and forming a dummy nanopattern using the nanoposts on the peripheral region.

### BRIEF DESCRIPTION OF DRAWINGS

The above and other aspects will be more apparent from the following description of example embodiments taken in conjunction with the accompanying drawings, in which:

FIG. 1 is a block diagram of an image sensor according to some example embodiments;

FIG. 2 is a circuit diagram of pixels included in a pixel array of the image sensor according to some example embodiments;

FIG. 3A is a plan view of an image sensor according to some example embodiments;

FIG. 3B is an enlarged plan view of portion P1 of FIG. 3A; according to some example embodiments

FIG. 4 is a cross-sectional view taken along line A-A′ of FIG. 3B according to some example embodiments;

FIG. 5 illustrates both an enlarged plan view of a pixel array region corresponding to R1 of FIG. 3B, showing metamicrolenses corresponding to pixels and a cross-sectional view taken along line B-B′ of the plan view according to some example embodiments;

FIG. 6 illustrates both an enlarged plan view of the peripheral region corresponding to R2 of FIG. 3B, showing a dummy nanopattern and a cross-sectional view taken along line C-C′ of the plan view according to some example embodiments;

FIG. 7 is a perspective view illustrating shapes of second nanoposts according to some example embodiments according to some example embodiments;

FIG. 8 is an enlarged plan view of portion P1 of FIG. 3A according to some example embodiments;

FIG. 9 is an enlarged view of a peripheral region corresponding to R3 of FIG. 8 according to some example embodiments;

FIG. 10 is a diagram illustrating a region corresponding to portion P1 of FIG. 3A according to some example embodiments;

FIG. 11 is a diagram illustrating a region corresponding to portion P1 of FIG. 3A according to some example embodiments;

FIGS. 12A, 12B, and 12C are enlarged plan views of portion P2 of FIG. 3A according to some example embodiments;

FIG. 13 is a cross-sectional view of an image sensor according to some example embodiments;

FIG. 14 is a cross-sectional view of an image sensor including an anti-reflective layer formed on the image sensor illustrated in FIG. 13 according to some example embodiments;

FIG. 15 is a cross-sectional view of an image sensor in which a portion of a nanostructure layer is used as a color separation lens array according to some example embodiments;

FIG. 16 is a cross-sectional view of an image sensor according to some example embodiments; and

FIGS. 17A, 17B, 17C, 17D, 17E, 17F, 17G, 17H and 17I are cross-sectional views, sequentially illustrating a method of manufacturing an image sensor according to some example embodiments.

### DETAILED DESCRIPTION

The present disclosure may be modified in various ways, and may have various embodiments, among which specific embodiments will be described in detail with reference to the accompanying drawings. However, it should be understood that the description of the specific embodiments of the present disclosure is not intended to limit the present disclosure to a particular mode of practice, and that the present disclosure is to cover all modifications, equivalents, and substitutes included in the spirit and technical scope of the present disclosure.

Hereinafter, example embodiments will be described with reference to the accompanying drawings. Each example embodiment provided in the following description is not excluded from being associated with one or more features of another example or another example embodiment also provided herein or not provided herein but consistent with the present disclosure. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

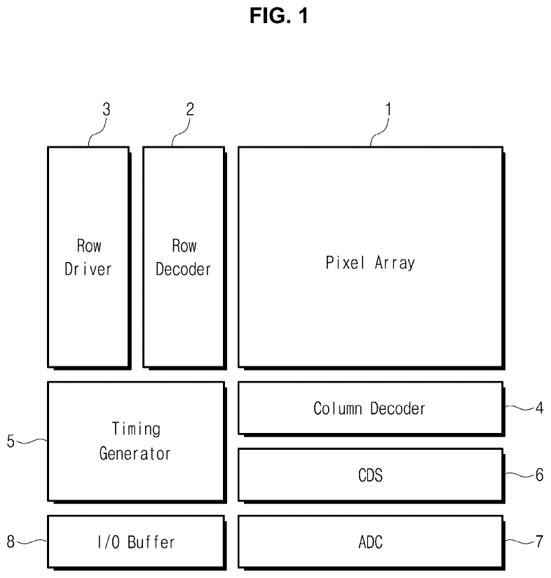

FIG. 1 is a block diagram of an image sensor according to some example embodiments.

Referring to FIG. 1, an image sensor according to some example embodiments may include a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 may include a plurality of pixels arranged in two directions, and the pixels may convert optical signals into electrical signals. The pixel array 1 may be driven by a plurality of driving signals (for example, a pixel select signal, a reset signal, and/or a charge transfer signal) transmitted from the row driver 3. The converted electrical signals may be provided to the correlated double sampler 6.

The row driver 3 may provide a plurality of driving signals to drive a plurality of pixels to the pixel array 1 based on a result decoded by the row decoder 2. When the pixels are arranged in a matrix, the driving signals may be provided in units of rows.

The timing generator 5 may provide a timing signal and a control signal to the row decoder 2 and the column decoder 4.

The correlated double sampler 6 may receive electrical signals generated from the pixel array 1, and may hold and sample the received signals. The correlated double sampler 6 may double-sample a specific noise level and a signal level of the electrical signal to output a difference level corresponding to a difference between the noise level and the signal level.

The analog-to-digital converter 7 may convert an analog signal, corresponding to the difference level output from the correlated double sampler 6, into a digital signal and output the digital signal.

The input/output buffer 8 may latch digital signals and sequentially output the latched signals to an image signal processor based on the decoding results of the column decoder 4.

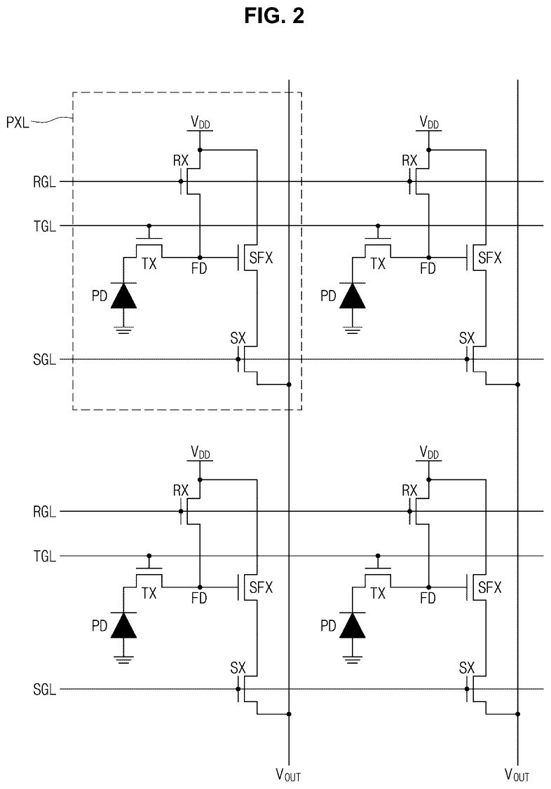

FIG. 2 is a circuit diagram of pixels included in a pixel array of the image sensor according to some example embodiments.

Referring to FIG. 2, the pixel array may include a plurality of pixels PXL, and the pixels PXL may be arranged in a matrix form. Each of the pixels PXL may include pixel transistors, and the pixel transistors may include a transfer transistor TX and logic transistors RX, SX, and SFX. The logic transistors RX, SX, and SFX may include a reset transistor RX, a select transistor SX, and a source follower transistor SFX. In addition, each of the pixels PXL may include a photodiode PD and a floating diffusion region FD.

The photodiode PD may generate and accumulate photocharges in proportion to the amount of externally incident light. The photodiode PD may include a photodiode, a phototransistor, a photogate, a pinned photodiode, or combinations thereof. The transfer transistor TX may transfer photocharges, generated from the photodiode PD, to the floating diffusion region FD. A transfer gate of the transfer transistor TX may be connected to a transfer gate line TGL. The floating diffusion region FD may receive and cumulatively store photocharges generated from the plurality of photodiodes PDs.

A gate of the source follower transistor SFX may be connected to the floating diffusion region FD. A drain terminal of the source follower transistor SFX may be connected to a power supply terminal V_{DD} that may receive a power supply voltage. The source follower transistor SFX may be controlled based on the amount of photocharges accumulated in the floating diffusion region FD.

The reset transistor RX may periodically reset charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to a power supply terminal V_{DD}. When the reset transistor RX is turned on, the power supply voltage at the power supply terminal V_{DD} may be applied to the floating diffusion region FD through the reset transistor RX. For example, when the reset transistor RX is turned on, the charges accumulated in the floating diffusion region FD may be discharged by the power supply voltage and the floating diffusion region FD may be reset.

The source follower transistor SFX may serve as a source follower buffer amplifier. The source follower transistor SFX may amplify a potential change in the floating diffusion region FD and output the amplified potential change to an output line V_{OUT}.

A gate of the select transistor SX may be connected to a select gate line SGL. A drain terminal of the select transistor SX may be connected to a source terminal of the source follower transistor SFX, and a source terminal of the select transistor SX may be connected to an output line V_{OUT}. Select transistors SX of pixels PXL to be read in units of rows may be selected by a select signal applied through a corresponding select gate line SGL. When the select transistor SX is turned on, the potential change amplified by the source follower transistor SFX may be output to the output line V_{OUT} through the select transistor SX.

In FIG. 2, each of the pixels PXL includes a single photodiode PD, but example embodiments are not limited thereto. In some example embodiments, each of the pixels PXL may include a plurality of photodiodes PD. A plurality of transfer transistors TX may be provided in each of the pixels PXL to correspond to the plurality of photodiodes PD. The plurality of photodiodes PD and the plurality of transfer transistors TX may each constitute a plurality of sub-pixels, and the sub-pixels may share the floating diffusion region FD and logic transistors RX, SX, and SFX of each of the pixels PXL.

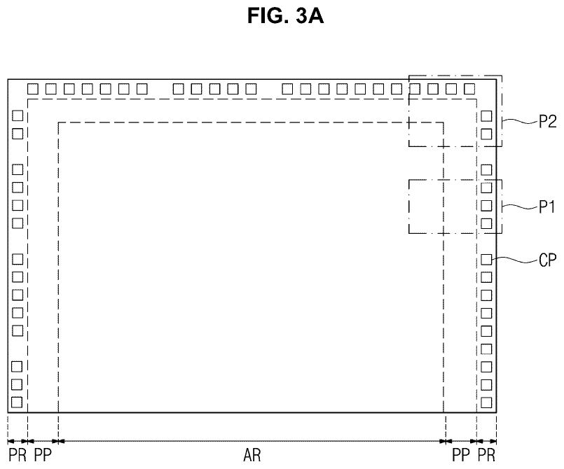

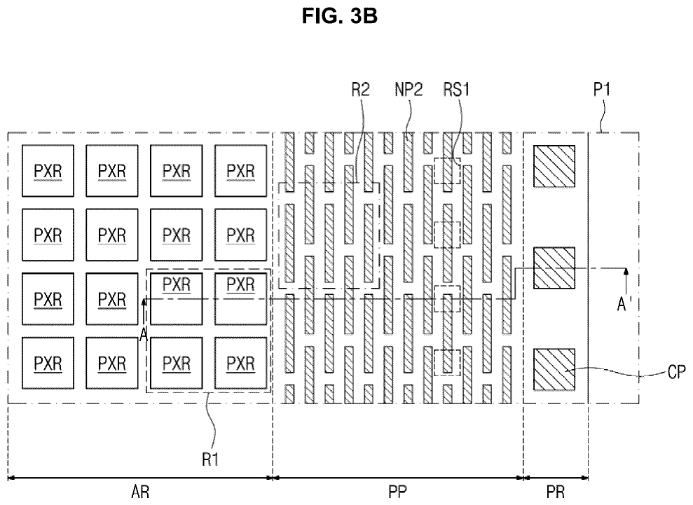

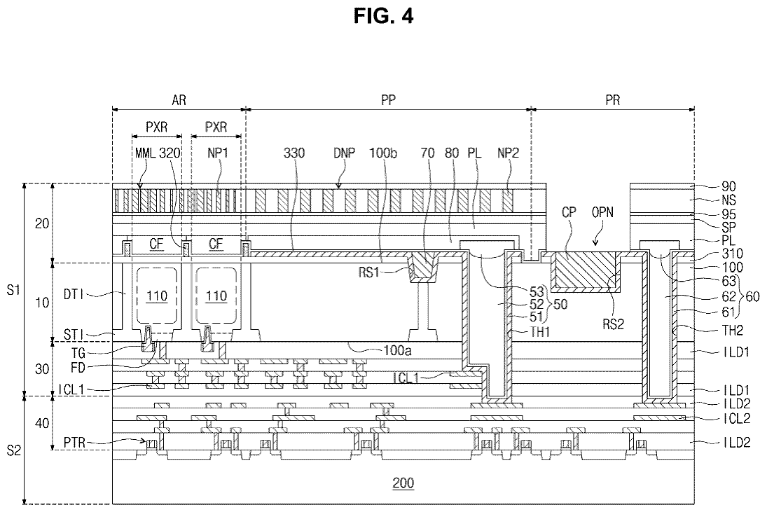

FIG. 3A is a plan view of an image sensor according to an example embodiment, and FIG. 3B is an enlarged plan view of portion P1 of FIG. 3A. FIG. 4 is a cross-sectional view taken along line A-A′ of FIG. 3B.

Referring to FIGS. 3A, 3B, and 4, the image sensor according to some example embodiments may include a first chip S1 and a second chip S2. The first chip S1 may be provided on the second chip S2, and for example may be stacked on the second chip S2. In this regard, the image sensor may have a stacked structure. The first chip S1 may be a sensor chip provided with a photoelectric conversion region 110. The second chip S2 may be a logic chip provided with a logic circuit. The first chip S1 and the second chip S2 may be bonded to each other by at least one of various bonding methods and may be electrically connected to each other by at least one of various connection methods.

The first chip S1 may include a photodiode layer 10, a light transmission layer 20, and a first interconnection layer 30. The photodiode layer 10 may be disposed between the light transmission layer 20 and the first interconnection layer 30. The photodiode layer 10 may include a first substrate 100, and the first substrate 100 may include a pixel array region AR, a peripheral region PP, and a pad region PR. The pixel array region AR may have a rectangular shape in plan view. However, the shape of the pixel array region AR is not limited thereto, and the pixel array region AR may be a shape, other than a rectangular shape, such as a circular shape.

The first substrate 100 may have a first surface 100a and a second surface 100b opposite the first surface 100a. In some example embodiments, the first substrate 100 may be a semiconductor substrate (for example, a silicon (Si) substrate, a germanium (Ge) substrate, or a silicon-germanium (SiGe) substrate).

The peripheral region PP may be disposed between the pixel array region AR and the pad region PR in plan view. In some example embodiments, the peripheral region PP may surround at least a portion of the pixel array region AR in plan view, and the pad region PR may surround at least a portion of the pixel array region AR and the peripheral region PP in plan view. However, example embodiments are not limited thereto. In some example embodiments, the peripheral region PP and the pad region PR may be provided on one or some of four sides of the pixel array region AR in plan view. For example, the peripheral region PP and the pad region PR may be provided on one or some of three sides of the pixel array region AR in plan view, as illustrated in FIG. 3A. In some example embodiments, the peripheral region PP and the pad region PR may be provided on all of the four sides of the pixel array region AR in plan view. In plan view, the pixel array region AR may correspond to a central portion of the first substrate 100 and the peripheral region PP and the pad region PR may correspond to an edge portion of the first substrate 100.

A deep trench isolation pattern DTI may be provided in the first substrate 100 to define a plurality of pixel regions PXR. A shallow trench isolation pattern STI may be provided in the first substrate 100 to define at least one active region in each of the pixel regions PXR. The shallow trench isolation pattern STI may be adjacent to a first surface 100a of the first substrate 100.

Photoelectric conversion regions 110 may be provided in each of the pixel regions PXR. The first substrate 100 may be doped with dopants having a first conductivity type, and the photoelectric conversion regions 110 may be doped with dopants having a second conductivity type, different from the first conductivity type. For example, the first conductivity type may be P-type, and the second conductivity type may be N-type.

A floating diffusion region FD may be provided in a corresponding active region of each of the pixel regions PXR. The floating diffusion region FD may be doped with dopants having the second conductivity type. A transfer gate TG may be provided on the corresponding active region on one side of the floating diffusion region FD. A gate dielectric layer may be disposed between the transfer gate TG and the corresponding active region. In some example embodiments, the transfer gate TG may fill a gate recess formed in the corresponding active region. The gate dielectric layer may extend to be disposed between the transfer gate TG and an inner surface of the gate recess.

In some example embodiments, other gates may be provided on corresponding active regions with the gate dielectric layer interposed therebetween. The other gates may include a reset gate, a source/follower gate, and a select gate. In some example embodiments, the other gates may further include a gate performing another function (for example, a dual conversion gain gate). Source/drain regions may be provided in corresponding active regions on opposite sides adjacent to each of the other gates. The other gates may be provided on corresponding active regions of each of the pixel regions PXR. Alternatively, the other gates may be provided on corresponding active regions of pixel regions PXR of pixels sharing the other gates.

As described above, the transfer gate TG and the other gates may be provided on the first surface 100a of the first substrate 100. However, example embodiments are not limited thereto. In some example embodiments, the transfer gate TG may be provided on the first surface 100a of the first substrate 100 and the other gates may be provided on an additional substrate. The additional substrate may have a third surface facing the first surface 100a and a fourth surface opposite the third surface. The other gates may be provided on the third surface or the fourth surface of the additional substrate with an additional gate dielectric layer interposed therebetween. An intermediate structure including the additional substrate and the other gates may be provided between the first chip S1 and the second chip S2. The intermediate structure may be bonded to the first and second chips S1 and S2 by at least one of various bonding methods. Hereinafter, for ease of description, example embodiments in which the transfer gate TG and the other gates are provided on the first surface 100a of the first substrate 100 will be described.

The deep trench isolation pattern DTI, the shallow trench isolation pattern STI, the photoelectric conversion regions 110, the floating diffusion regions FD, and the transfer gates TG may be included in the photodiode layer 10.

Pixels including the photoelectric conversion regions 110 of the pixel array region AR may convert incident light into electrical signals (for example, pixel signals).

The light transmission layer 20 may be provided on the second surface 100b of the first substrate 100. The light transmission layer 20 is a layer through which light traveling from the outside to the photoelectric conversion region 110 is transmitted, and the second surface 100b of the first substrate 100 may be an incident light surface on which light is incident. The light transmission layer 20 may include a transmission insulating layer 310, a grid 320, a protective layer 330, color filters CF, and a nanostructure layer NS.

The transmission insulating layer 310 may cover the second surface 100b of the first substrate 100. The transmission insulating layer 310 may have a single-layer structure or a multilayer structure. In some example embodiments, the transmission insulating layer 310 may include a fixed charge layer and/or an anti-reflective layer.

The fixed charge layer may have negative fixed charges. Therefore, holes may be accumulated in a location adjacent to the fixed charge layer, such as an interface between the fixed charge layer and the first substrate 100 and/or a portion of the first substrate 100 adjacent to the second surface 100b. As a result, the fixed charge layer may effectively reduce dark current and/or white spots. In some example embodiments, the fixed charge layer may be formed of a metal oxide or metal fluoride including at least one of hafnium (Hf), zirconium (Zr), aluminum (Al), tantalum (Ta), titanium (Ti), yttrium (Y), or a lanthanoid. For example, the fixed charge layer may be formed of a hafnium oxide or an aluminum oxide.

The anti-reflective layer may reduce or significantly reduce reflection of light incident on the second surface 100b. For example, the anti-reflective layer may include at least one of a titanium oxide, a silicon nitride, a silicon oxide, or a hafnium oxide. When the transmission insulating layer 310 includes the fixed charge layer and the anti-reflective layer, the fixed charge layer may be in contact with the second surface 100b of the first substrate 100, and the anti-reflective layer may be disposed on the fixed charge layer. However, example embodiments are not limited thereto. In some example embodiments, the transmission insulating layer 310 may include either the fixed charge layer or the anti-reflective layer, or may further include an additional insulating layer.

The grid 320 may have a grid shape with openings in a planar view. In some example embodiments, the openings of the grid 320 may vertically overlap the pixel regions PXR. The grid 320 may guide the incident light such that the incident light is incident into the photoelectric conversion regions 110. In some example embodiments, the grid 320 may include a light-shielding pattern and/or a low refractive index pattern. For example, the light-shielding pattern may include at least one of titanium, titanium nitride, tantalum, tantalum nitride, or tungsten. The low refractive index pattern may have a refractive index, lower than refractive indices of the color filters CF. For example, the low refractive index pattern may have a refractive index of about 1.1 to about 1.3. For example, the low refractive index pattern may include an organic material.

A protective layer 330 may conformally cover surfaces (for example, an upper surface and side surfaces) of the grid 320, and the transmission insulating layer 310 exposed by the openings of the grid 320. In some example embodiments, the protective layer 330 may be formed of an insulating material having a high-k dielectric constant. For example, the protective layer 330 may include an aluminum oxide or a hafnium oxide.

The color filters CF may fill the openings of the grid 320. The color filters CF may be disposed on the protective layer 330. The color filters CF may vertically overlap the photoelectric conversion regions 110. In some example embodiments, the color filters CF may include a first color filter having a first color, a second color filter having a second color, and a third color filter having a third color. In an example embodiment, the first color may be one of red, green, and blue, the second color may be another one of red, green, and blue, and the third color may be the remaining one of red, green, and blue. Alternatively, the first color may be one of magenta, cyan, and yellow, the second color may be another one of magenta, cyan, and yellow, and the third color may be the remaining one of magenta, cyan, and yellow. However, example embodiments are not limited thereto. The first to third colors may be various other colors.

Each of the color filters CF may vertically overlap a corresponding photoelectric conversion region among the photoelectric conversion regions 110. However, example embodiments are not limited thereto. In some example embodiments, each of the color filters CF may vertically overlap a plurality of adjacent photoelectric conversion regions 110. In some example embodiments, each of the color filters CF may overlap a portion of a corresponding photoelectric conversion region among the photoelectric conversion regions 110. In some example embodiments, depending on locations of the color filters CF, each of some color filters CF may overlap a corresponding photoelectric conversion region among the photoelectric conversion regions 110, and each of other color filters CF may overlap only a portion of a corresponding photoelectric conversion region among the photoelectric conversion regions 110.

The photoelectric conversion regions 110 corresponding to each of the color filters CF may be arranged in a matrix form. For example, the corresponding photoelectric conversion regions 110 may be arranged in a 2×2 matrix form, a 3×3 matrix form, or a 4×4 matrix form.

A nanostructure layer NS may be provided on the color filters CF.

A planarization layer PL, a spacer SP, and an etch-stop layer 95 may be provided between the nanostructure layer NS and the color filters CF.

The etch-stop layer 95 may be provided to prevent components, disposed below the etch-stop layer 95 (for example, the spacer SP and the planarization layer PL) from being overetched when the nanostructure layer NS is formed using an etching process. The etch-stop layer 95 may include HfO₂, SiO₂, and/or AlO.

The planarization layer PL may cover upper surfaces of the color filters CF between the etch-stop layer 95 and the color filters CF. The planarization layer PL may include at least one of various organic materials, for example, an organic polymer. Examples of the organic polymer include, epoxy resin, polyimide, polycarbonate, polyacrylic, and polymethyl methacrylate (PMMA), but example embodiments are not limited thereto. The planarization layer PL may be selectively provided, and may be omitted when a spacer SP to be described below has a sufficient thickness.

The spacer SP may secure a gap between the color filters CF and the nanostructure layer NS. For example, the thickness of the spacer SP may be adjusted to secure a focal length of metamicrolenses MML to be described later. The spacer SP may be selectively provided in addition to the planarization layer PL, and may be omitted when the planarization layer PL has a sufficient thickness.

The nanostructure layer NS may include a plurality of metamicrolenses MML in the pixel array region AR and may include a dummy nanopattern DNP in the peripheral region PP. The nanostructure layer NS will be described later in more detail.

As illustrated in FIG. 4, the grid 320 may be vertically aligned with a deep trench isolation pattern DTI, and the metamicrolens MML and the color filter CF may be vertically aligned with a corresponding photoelectric conversion region 110. However, example embodiments are not limited thereto.

In some example embodiments, light may be radially incident on the entire second surface 100b of the first substrate 100 from an objective lens overlapping a central portion of the pixel array region AR. For example, the incident light may be perpendicularly incident on the photoelectric conversion region 110 within the central portion of the pixel array region AR, but may be obliquely incident on the photoelectric conversion region 110 within an edge portion of the pixel array region AR. The grid 320 on the central portion of the pixel array region AR may be vertically aligned with the deep trench isolation pattern DTI, and the metamicrolens ML and the color filter CF on the central portion of the pixel array region AR may be vertically aligned with a corresponding photoelectric conversion region 110. In contrast, the grid 320 on the edge portion of the pixel array region AR may be laterally shifted from the deep trench isolation pattern DTI, and the metamicrolens ML and color filter CF on the edge portion of the pixel array region AR may be laterally shifted from a corresponding photoelectric conversion region 110. The grid 320, the metamicrolens ML, and the color filter CF on the edge portion of the pixel array region AR may be laterally shifted in a direction toward the central portion from the edge portion of the pixel array region AR. In some example embodiments, the degrees of shift of the portions of the grid 320, the metamicrolenses, and the color filters CF on the edge portion of the pixel array region AR may sequentially decrease in a direction toward the central portion from the edge portion of the pixel array region AR.

The first interconnection layer 30 may be provided on the first surface 100a of the first substrate 100. The first interconnection layer 30 may cover the first surface 100a of the first substrate 100 and may include first interlayer dielectrics ILD1 and first interconnection lines ICL1. The first interconnection lines ICL1 may be provided between the first interlayer dielectrics ILD1. The first interconnection lines ICL1 may be electrically connected to pixel transistors (for example, a transfer transistor, a reset transistor, a source follower transistor, and a select transistor) through first contact plugs and/or may electrically connect the pixel transistors.

The second chip S2 may include a second substrate 200, peripheral transistors PTR formed on the upper surface of the second substrate 200, and a second interconnection layer 40 provided on the upper surface of the second substrate 200 to cover the peripheral transistors PTR. The second substrate 200 may be a semiconductor substrate such as a silicon substrate, a germanium substrate, or a silicon-germanium substrate. The second interconnection layer 40 may include second interlayer dielectrics ILD2 and second interconnection lines ICL2 between the second interlayer dielectrics ILD2. The second interconnection lines ICL2 may be electrically connected to the peripheral transistors PTR through second contact plugs and/or may electrically connect the peripheral transistors PTR. The second interconnection lines ICL2 and the peripheral transistors PTR may constitute a peripheral circuit of the image sensor (for example, the row decoder, the row driver, the column decoder, the timing generator, the correlated double sampler, the analog-to-digital converter, and/or the input/output buffer of FIG. 1).

The first chip S1 may be stacked on the second chip S2, and the first and second chips S1 and S2 may be bonded to each other. The second interconnection layer 40 may be disposed between the first interconnection layer 30 and the second substrate 200. In some example embodiments, a lowermost first interlayer dielectric among the first interlayer dielectrics ILD1 may be bonded to an uppermost second interlayer dielectric among the second interlayer dielectrics ILD2.

In some example embodiments, the first chip S1 may be electrically connected to the second chip S2 through one or more connection structures 50 and 60. In some example embodiments, the connection structures 50 and 60 may include a first connection structure 50 and a second connection structure 60.

The first connection structure 50 may include a first through-electrode 51, a first filling insulation pattern 52, and a first capping pattern 53. The first through-electrode 51 may be provided in a first through-hole TH1 penetrating through a portion of the first substrate 100, the first interconnection layer 30, and the second interconnection layer 40 in the peripheral region PP. In an example embodiment, the first through-hole TH1 may also penetrate through the transmission insulating layer 310. The first through-electrode 51 may conformally cover an inner surface of the first through-hole TH1. The first through-hole TH1 may expose a corresponding one of the first interconnection lines ICL1 and a corresponding one of the second interconnection lines ICL2. Thus, the first through-electrode 51 may be electrically connected to the corresponding one of the first interconnection lines ICL1 and the corresponding one of the second interconnection lines ICL2. The first filling insulation pattern 52 may be provided on the first through-electrode 51 to fill the first through-hole TH1. The first capping pattern 53 may cover an upper surface of the first filling insulation pattern 52.

According to some example embodiments, a first recess RS1 may be recessed inwardly of the first substrate 100 from the second surface 100b of the first substrate 100 of the peripheral region PP. The first recess RS1 may expose a filling conductive pattern of the deep trench isolation pattern DTI. In an example embodiment, the first recess RS1 may penetrate through the transmission insulating layer 310. The first recess RS1 may be disposed on one side of the first through-hole TH1. The first through-electrode 51 may extend upwardly of the second surface 100b of the first substrate 100 and an inner surface of the first recess RS1. Thus, the first through-electrode 51 may be electrically connected to the filling conductive pattern of the deep trench isolation pattern DTI. During operation of the image sensor, a negative bias voltage may be applied to the filling conductive pattern of the deep trench isolation pattern DTI through the first through-electrode 51. In an example embodiment, the first through-electrode 51 may further extend toward the pixel array region AR to cover most of the peripheral region PP. A portion of the first through-electrode 51, covering the peripheral region PP, may serve as a light-shielding pattern. In an example embodiment, unlike what is illustrated in FIG. 4, the portion of the first through-electrode 51 serving as the light-shielding pattern may be separated from a portion of the first through-electrode 51 covering the inner surfaces of the first recess RS1 and the first through-hole TH1.

A conductive plug 70 may fill the remaining region of the first recess RS1. The conductive plug 70 may be in contact with the first through-electrode 51 provided in the first recess RS1. In an example embodiment, the conductive plug 70 may be formed of a conductive material having a lower resistance than the first through-electrode 51.

As illustrated in FIG. 4, the protective layer 330 may cover the first through-electrode 51 and the conductive plug 70. The protective layer 330 may be provided between the first through-electrode 51 and the first filling insulation pattern 52 within the first through-hole TH1. Alternatively, the protective layer 330 may be disposed between the first through-electrode 51 and the transmission insulating layer 310. The protective layer 330 may not be present in the first through-hole TH1 and the first recess RS1. For example, the first through-hole TH1 and the first recess RS1 may penetrate through the protective layer 330 and the transmission insulating layer 310.

A filtering pattern 80 may cover the first through-electrode 51 and the first capping pattern 53. The filtering pattern 80 may block light of a specific wavelength. For example, the filtering pattern 80 may block ultraviolet light. For example, the filtering pattern 80 may include a blue color filter, but example embodiments are not limited thereto.

The second connection structure 60 may include a second through-electrode 61, a second filling insulation pattern 62, and a second capping pattern 63. The second through-electrode 61 may be provided in a second through-hole TH2 penetrating through at least a portion of the first substrate 100, the first interconnection layer 30, and the second interconnection layer 40 in the pad region PR. In an example embodiment, the second through-hole TH2 may further penetrate through the transmission insulating layer 310. The second through-electrode 61 may conformally cover an inner surface of the second through-hole TH2. The second through-hole TH2 may expose a corresponding second interconnection line among the second interconnection lines ICL2. Thus, the second through-electrode 61 may be electrically connected to the corresponding second interconnection line among the second interconnection lines ICL2. The second filling insulation pattern 62 may be provided on the second through-electrode 61 to fill the second through-hole TH2. The second capping pattern 63 may cover the upper surface of the second filling insulation pattern 62. Similarly to the first connection structure 50, the protective layer 330 may be disposed between the second through-electrode 61 and the second filling insulation pattern 62. Alternatively, the protective layer 330 may be disposed below the second through-electrode 61, and the second through-hole TH2 may also penetrate through the protective layer 330.

According to some example embodiments, a second recess RS2 may be recessed inwardly of the first substrate 100 from the second surface 100b of the first substrate 100 of the pad region PR. The second recess RS2 may be disposed on one side of the second through-hole TH2. In an example embodiment, the second recess RS2 may further penetrate through the transmission insulating layer 310. In some example embodiments, the second through-electrode 61 may extend inwardly of the second surface 100b of the first substrate 100 and an inner surface of the second recess RS2.

A connection pad CP may fill the remaining region of the second recess RS2. The connection pad CP may be in contact with the second through-electrode 61. Thus, the connection pad CP may be electrically connected to the second chip S2 through the second through-electrode 61. The connection pad CP may be used for electrical connection to an external device. In some example embodiments, the connection pad CP may receive various signals (for example, a command signal and/or a control signal) transmitted from the external device, and various electrical signals generated from the image sensor may be transmitted to the external device through the connection pad CP. For example, a connector such as a bonding wire may be connected to the connection pad CP, and the connection pad CP may be electrically connected to the external device through the connector. In an example embodiment, the connection pad CP may be formed of a conductive material having a lower resistance than the second through-electrode 61.

Each of the first and second through-electrodes 51 and 61 may be formed of a conductive material. For example, the first and second through-electrodes 51 and 61 may be formed of a metal (for example, tungsten (W), titanium (Ti), tantalum (Ta), or the like) and/or a conductive metal nitride (for example, titanium nitride (TiN), tantalum nitride (TaN), tungsten nitride (WN), or the like). In an example embodiment, the first and second through-electrodes 51 and 61 may be formed of the same material. Each of the first and second filling insulation patterns 52 and 62 may be formed of an insulating material. In an example embodiment, the first and second filling insulation patterns 52 and 62 may be formed of the same insulating material. Each of the first and second capping patterns 53 and 63 may be formed of an insulating material. In an example embodiment, the first and second capping patterns 53 and 63 may be formed of the same insulating material. As described above, resistance of the conductive plug 70 may be lower than resistance of the first through-electrode 51, and resistance of the connection pad CP may be lower than resistance of the second through-electrode 61. In an example embodiment, the conductive plug 70 and the connection pad CP may be formed of the same conductive material. For example, the conductive plug 70 and the connection pad CP may include aluminum (Al).

A passivation layer 90 may be provided on the nanostructure layer NS provided on the second surface 100b of the first substrate 100. The passivation layer 90 may cover the pixel array region AR, the peripheral region PP, and the pad region PR. An opening OPN may penetrate through the passivation layer 90, the nanostructure layer NS, the etch-stop layer 95, the spacer SP, and the planarization layer PL on the pad region PR to expose the connection pad CP.

As described above, the connection pad CP may be disposed in the second recess RS2 formed in the first substrate 100. However, example embodiments are not limited thereto. In some example embodiments, the connection pad CP may be disposed at another location.

In an example embodiment, the nanostructure layer NS provided on the color filters CF may have different shapes on the pixel array region AR and the peripheral region PP. Hereinafter, the nanostructure layer NS on the pixel array region AR will be described first, and the nanostructure layer NS on the peripheral region PP will then be described.

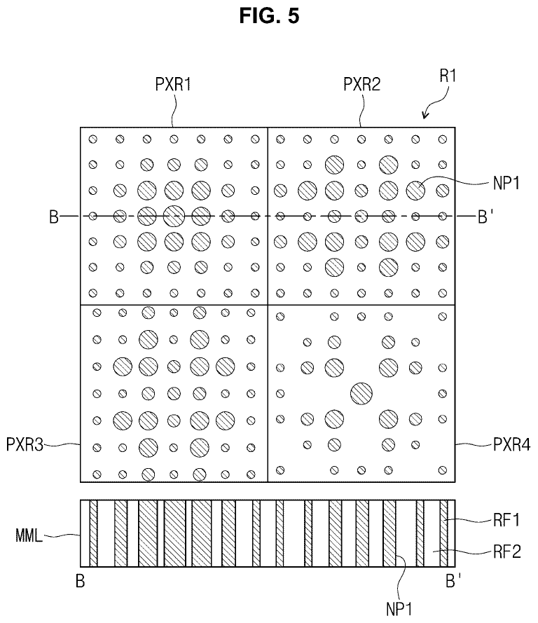

FIG. 5 shows a pixel array region corresponding to R1 of FIG. 3B, illustrating both a plan view of metamicrolenses corresponding to pixels and a cross-sectional view taken along line B-B′ of the plan view.

Referring to FIGS. 3A, 3B, 4, and 5, a single photoelectric conversion region 110, a single color filter CF, and a single metamicrolens MML may be provided for each pixel region PXR. However, at least one of the photoelectric conversion region 110, the color filter CF, or a metamicrolens MML corresponding to the single pixel region PXR may be provided in plural. For example, two photoelectric conversion regions 110 may correspond to a single color filter CF and a single metamicrolens MML, or four photoelectric conversion regions 110 and four color filters CF may correspond to a single metamicrolens MML. Hereinafter, for ease of description, a description will be mainly provided for the case in which a single photoelectric conversion region 110, a single color filter CF, and a single metamicrolens MML correspond to a single pixel region PXR.

The color filters CF and metamicrolenses MML provided for each of the pixel regions PXR may be arranged in a matrix form. In an example embodiment, a plurality of pixel regions PXR may constitute a single unit pixel region, and unit pixel regions may also be arranged in a matrix form. A single unit pixel region may include various numbers of pixel regions PXR, for example, two pixel regions PXR, four pixel regions PXR, nine pixel regions PXR, or 16 pixel regions PXR. In FIG. 5, as an example, four pixel regions PXR arranged in a 2×2 matrix form are illustrated as constituting a single unit pixel region.

In FIG. 5, when a single unit pixel region includes a 2×2 matrix of pixel regions, for example, first to fourth pixel regions PXR1, PXR2, PXR3, and PXR4, the single unit pixel region may have a Bayer pattern. Within the unit pixel region, a single red pixel region and a single blue pixel region may be disposed in a direction of one diagonal, and two green pixel regions may be disposed in a direction of another diagonal. For example, the first pixel region PXR1 may be a red pixel region, the second and third pixel regions PXR2 and PXR3 may be green pixel regions, and the fourth pixel region PXR4 may be a blue pixel region.

Metamicrolenses MML, flat microlenses, may be disposed on the color filters CF. Each of the metamicrolens MML may include a sub-wavelength periodic nanostructure to locally adjust a refractive index of incident light. The nanostructure may locally adjust a refractive index of incident light to control polarization, phase, and size of light. In an example embodiment, phase delay of transmitted light may be adjusted by adjusting a ratio of materials, locally having different refractive indices, in a portion through which light passes.

For example, a metamicrolens may include a first nanorefractive pattern RF1 and a second nanorefractive pattern RF2 formed of two or more materials having different refractive indices. The second nanorefractive pattern RF2 fills a gap between the first nanorefractive patterns RF1. In an example embodiment, the first nanorefractive pattern RF1 may include a material having a relatively high refractive index, while the second nanorefractive pattern RF2 includes a material having a relatively low refractive index. For example, the first nanorefractive pattern RF1 may include a dielectric material, such as TiO₂, GaN, ZnS, ZnSe, or SiNₓ (for example, Si₃N₄), having a relatively high refractive index and low absorption in a visible light band. The second nanorefractive pattern RF2 may include a dielectric material, such as SiO₂, SiCOH, siloxane-based spin-on-glass (SOG), or air, having a relatively low refractive index and low absorption in the visible light band. The metamicrolens may include a plurality of first nanoposts NP1 as the first nanorefractive pattern.

At least a portion of metamicrolenses MML may be disposed to overlap the photoelectric conversion regions 110 in a vertical direction (for example, in a third direction). The metamicrolenses MML may be provided at locations corresponding to the photoelectric conversion regions 110.

In order for each metamicrolens MML to serve as a convex lens that converges light, an effective refractive index of the metamicrolens MML may be highest in a certain region of the metamicrolens MML and may gradually decrease in a direction toward a periphery of that certain region. For example, a ratio of the first nanorefractive pattern RF1 to the second nanorefractive pattern RF2 may be highest in a certain region of the metamicrolens and may gradually decrease in a direction toward a periphery of the certain region.

Diameters and arrangements of the first nanoposts NP1 may vary depending on the location of the first nanoposts NP1 in the pixel array region AR of the first nanoposts NP1. When four pixel regions PXR constituting a unit pixel region are referred to as first to fourth pixel areas PXR1, PXR2, PXR3, and PXR4, diameters and arrangements of the first nanoposts NP1 in the first to fourth pixel region PXR1, PXR2, PXR3, and PXR4 may be set to be different from each other.

When light passes through a predetermined material, phase modulation may occur due to a refractive index of the material. In an example embodiment, the metamicrolenses MML may be manufactured using two materials having different effective refractive indices as described above, and a phase of light passing through the metamicrolenses may change as a diameter of the first nanoposts NP1 having a high refractive index varies.

In an example embodiment, the color filters CF, the grid 320, and the metamicrolenses MML have been described as being provided to overlap a location corresponding to each pixel. However, example embodiments are not limited thereto. For example, at least one of the color filters CF, the grids 320, and the metamicrolenses MML may be shifted (i.e., offset) by a predetermined amount from the location corresponding to each pixel.

The shift amount of the at least one of the color filters CF, the grids 320, and the metamicrolenses MML may be intentionally selected to optimize an optical path in consideration of an angle of light traveling from the outside to a pixel.

A passivation layer 90 may be provided on the metamicrolenses MML. The passivation layer 90 may have a single-layer structure or a multilayer structure. The passivation layer 90 may not only serve as a protective layer to protect the metamicrolenses MML, but also serve as an anti-reflection pattern to prevent light from being reflected from an upper surface of the metamicrolenses MML while transmitting light. The passivation layer 90 may be formed of various materials, such as hafnium oxide, silicon oxide, silicon nitride, silicon oxynitride, silicon carbide, silicon carbonitride, silicon carbonoxynitride, zirconium oxide, titanium oxide, and/or aluminum oxide (alumina, Al₂O₃). The passivation layer 90 may prevent the reflection of light such that light traveling from the metamicrolenses MML toward the second surface 100b may smoothly reach the photoelectric conversion region 110.

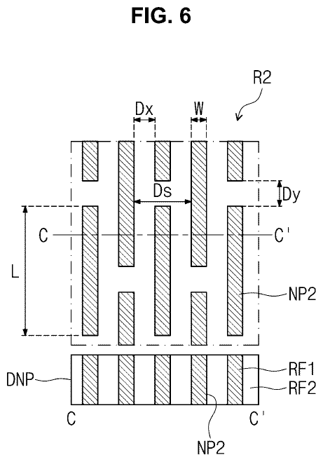

FIG. 6 is an enlarged plan view of the peripheral region corresponding to R2 of FIG. 3B, illustrating both a plan view of the peripheral region provided with a dummy nanopattern and a cross-sectional view taken along line C-C′ of the plan view.

Referring to FIG. 6, a dummy nanopattern DNP may be disposed on the peripheral region PP. The dummy nanopattern DNP is provided to alleviate stress that may occur between the pixel array region AR, the peripheral region PP, and/or the pad region PR. The dummy nanopattern DNP, such as a metamicrolenses MML, may include nanostructures formed of different materials.

Various materials having different coefficients of thermal expansion are used in the pixel array region AR, the peripheral region PP, and the pad region PR to manufacture an image sensor. Components formed on the pixel array region AR, the peripheral region PP, and the pad region PR may include organic materials, inorganic materials, or organic and inorganic materials having a large difference in coefficient of thermal expansion. During a manufacturing process and/or an evaluation process, the image sensor may be heated and exposed to different temperatures. Materials having different coefficients of thermal expansion expand to different degrees during a manufacturing process, which results in stress being applied to adjacent components. The stress may cause cracking in at least one of the pixel array region AR, the peripheral region PP, and the pad region PR, for example, in the peripheral region PP and the pad region PR. The cracking may propagate to other adjacent region along vulnerable portions. In an example embodiment, a dummy nanopattern DNP including different materials may be formed on the peripheral region PP, so that the stress applied to the peripheral region PP and a region adjacent to the peripheral region PP may be alleviated or buffered by the dummy nanopattern DNP.

The dummy nanopattern DNP may include a first nanorefractive pattern RF1 and a second nanorefractive pattern RF2. The dummy nanopattern DNP may include a plurality of second nanoposts NP2 as the first nanorefractive pattern RF1. The first nanorefractive pattern RF1 may be provided as a plurality of nanoposts NP disposed on a plane, and the second nanorefractive pattern RF2 may be provided to fill the remaining regions excluding the nanoposts NP.

The first nanorefractive pattern RF1 and the second nanorefractive pattern RF2 may include different materials, for example, materials having different coefficients of thermal expansion.

In an example embodiment, the first nanorefractive pattern RF1 and the second nanorefractive pattern RF2 of the dummy nanopattern DNP may include the same materials as the first nanorefractive pattern RF1 and the second nanorefractive pattern RF2 of the metamicrolens MML, respectively. In addition, the first nanorefractive pattern RF1 and the second nanorefractive pattern RF2 of the dummy nanopattern DNP may be manufactured in the same operations as the first nanorefractive pattern RF1 and the second nanorefractive pattern RF2 of the metamicrolens MML, respectively. The dummy nanopattern DNP may be manufactured in the same operations as the metamicrolenses MML without an additional process of forming the dummy nanopattern DNP.

In an example embodiment, each of the second nanoposts NP2 may have a bar shape elongated in one direction in plan view, and may penetrate through the nanostructure layer NS in cross-section view. In an example embodiment, each of the second nanoposts NP2 may have a rectangular prism shape.

In plan view, an extending direction of the second nanoposts NP2 may be a direction intersecting (for example, substantially perpendicular to) a direction in which cracking occurs due to differences in coefficients of thermal expansion. Two components including materials having different coefficients of thermal expansion may cause thermal stress in the peripheral region PP during the manufacturing process or during the evaluation operation after manufacturing. For example, heat may be applied to the image sensor during the manufacturing process and/or the evaluation operation. For example, the planarization layer PL and the nanostructure layer NS may be formed of an organic material and an inorganic material having different coefficients of thermal expansion, respectively, and may expand to different degrees when heat is applied during the manufacturing process or during the evaluation operation after manufacturing. A difference in thermal expansion between the planarization layer PL and the nanostructure layer NS may cause a large amount of thermal stress in a region, in which the planarization layer PL and the nanostructure layer NS are formed, and in adjacent regions. The thermal stress may cause cracking in structurally vulnerable portions on the first substrate 100. The cracking may mainly propagate in direction from the pad region PR toward the peripheral region PP and in a direction from the peripheral region PP toward the pixel array region AR along vulnerable portions.

In plan view, the second nanoposts NP2 may extend in a direction, substantially perpendicular to a direction in which stress is applied, to alleviate or buffer the stress. For example, the second nanoposts NP2 may extend in a direction, parallel to a boundary between the pixel array region AR and the peripheral region PP. Alternatively, the second nanoposts NP2 may extend in a direction, parallel to a boundary between the peripheral region PP and the pad region PR.

In an example embodiment, each of the second nanoposts NP2 may have various sizes and shapes. For example, in plan view, the second nanopost NP2 may have a bar shape elongated in a vertical direction. A ratio of a width W of the second nanopost NP2 to a length L of the second nanopost NP2 may be 1:2 to 1:7.

A ratio of a horizontal distance Dx between two adjacent second nanoposts NP2 to a vertical distance Dy therebetween may be 1:0.8 to 1:1.2. A ratio of the vertical distance Dy between two adjacent second nanoposts NP2 to a width W of the second nanopost NP2 may be 1:1 to 1:2. In addition, a horizontal distance Ds from one second nanopost NP2 to the most distant second nanopost NP2 at a specific point may be 0.6 to 1.1 times the length L of the second nanopost NP2. However, the size of the second nanoposts NP2 is not limited thereto and may have various other values.

In an example embodiment, when a plurality of second nanoposts NP2 are arranged in a horizontal direction, the second nanoposts NP2 may be arranged in a zigzag manner such that horizontal locations of one-end portions of the second nanoposts NP2 do not match each other.

In an example embodiment, the second nanoposts NP2 may be provided with a density similar to or substantially the same as that of the first nanoposts NP1. For example, in plan view, the density of the second nanoposts NP2 per unit area may be about 70% to about 130%, or about 80% to about 120%, or about 90% to about 110%, or 100% of the density of the first nanoposts NP1 per unit area. When the density of the first nanoposts NP1 and the density of the second nanoposts NP2 are similar or substantially the same, a process deviation in the pixel array region AR, the peripheral region PP, and the pad region PR may be reduced in a process of forming the nanostructure layer NS. For example, when the upper surface of the nanostructure layer NS is chemically mechanically polished, there may be an issue in which the degrees of polishing of the pixel array region AR and the peripheral region PP are different from each other when the density of the pixel array region AR and the density of the peripheral region PP are different from each other. According to an example embodiment, the density of the first nanoposts NP1 on the pixel array region AR is similar or substantially the same as the density of the second nanoposts NP2 on the peripheral region PP, so that the degrees of polishing of the pixel array region AR and the peripheral region PP may be adjusted to be substantially the same.

As described above, in an example embodiment, the dummy nanopattern DNP, for example, the second nanoposts NP2, may be provided on the peripheral region PP to alleviate stress applied to the peripheral region PP and regions adjacent to the peripheral region PP (the pixel array region AR and/or the pad region PR).

In an example embodiment, the second nanoposts NP2 may have various shapes.

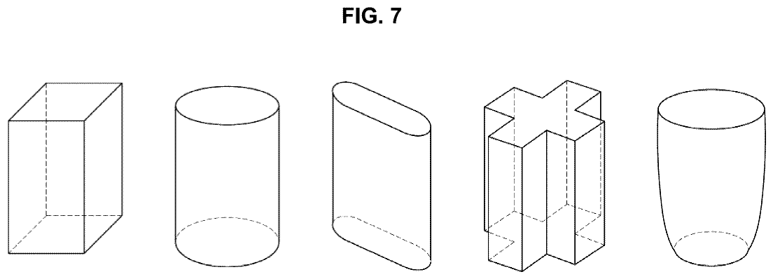

FIG. 7 is a perspective view illustrating exemplary shapes of second nanoposts according to some example embodiments.

Referring to FIG. 7, the second nanopost NP2 according to an example embodiment may have various columnar shapes. For example, an upper surface and a lower surface of the second nanopost NP2 may each have a rectangular shape or cross-like polygonal shape. Alternatively, the upper surface and the lower surface of the second nanopost NP2 may each have a circular shape. Alternatively, the upper surface and the lower surface of the second nanopost NP2 may each have a closed figure including straight lines and curves. Alternatively, the second nanopost NP2 may have polygonal upper and lower surfaces with rounded edges in plan view. Alternatively, the second nanopost NP2 may have a shape varying depending on a manufacturing process margin during a manufacturing process thereof, so that the upper surface and the lower surface of the second nanopost NP2 may have different sizes.

In an example embodiment, the second nanoposts NP2 in the peripheral region PP may have the same shape overall. However, example embodiments are not limited thereto, and the second nanoposts NP2 may have different shapes depending on locations thereof. For example, the second nanoposts NP2 may have a rectangular prism shape with a relatively large upper surface area in one region of the peripheral region PP and a rectangular prism shape with a relatively small upper surface area in another region of the peripheral region PP. Alternatively, the second nanoposts NP2 may have a rectangular prims shape in one region of the peripheral region PP and a cross-like columnar shape in another region of the peripheral region PP.

As described above, the second nanoposts NP2 may be provided with various shapes. Therefore, for ease of description, the second nanoposts NP2 will be described below as having a square prism shape. In the following example embodiments, differences from the above-described embodiments will be mainly described for ease of description.

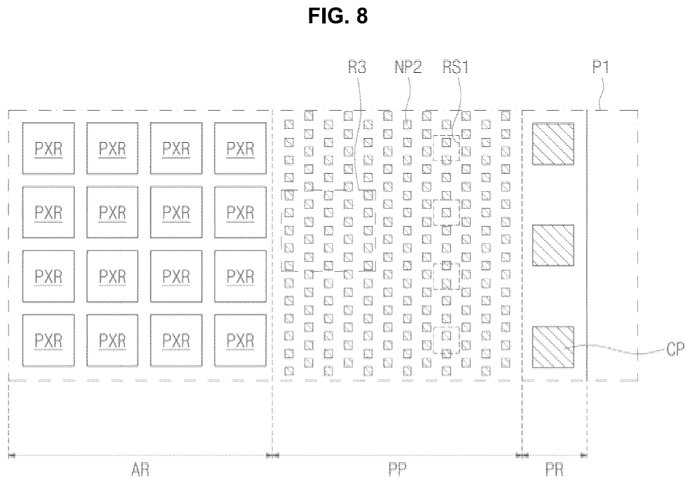

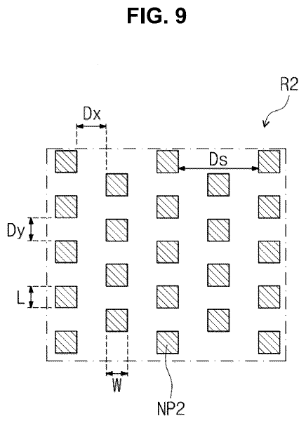

FIG. 8 is an enlarged plan view of portion P1 of FIG. 3A, and FIG. 9 is an enlarged view of a peripheral region corresponding to R3 of FIG. 8.

Referring to FIGS. 8 and 9, each of the second nanoposts NP2 may have a square prism shape.

In a single second nanopost NP2 according to an example embodiment, a ratio of a width W of the second nanopost NP2 to a length L of the second nanopost NP2 may be 1:0.9 to 1:1.1, or 1:1. In plan view, the second nanoposts NP2 may be arranged in a zigzag manner in a horizontal direction and/or a vertical direction.

The ratio of the horizontal distance Dx between two adjacent second nanoposts NP2 to the vertical distance Dy may be 1:0.9 to 1:1.1, or 1:1. The ratio of the vertical distance Dy between two adjacent second nanoposts NP2 to the length L of the second nanopost may be 1:0.9 to 1:1.1, or 1:1. In addition, a horizontal distance Ds from a specific point to the most distant second nanopost NP2 with respect to another one second nanopost NP2 may be 1.8 to 2.2 times the length L of the second nanopost. However, the shape and size of each second nanopost NP2 are not limited thereto and may vary in various ways.

In an example embodiment, the second nanoposts NP2 may be disposed at similar densities in the horizontal and vertical directions on a unit area. The second nanoposts NP2 may be provided at similar densities in the horizontal and vertical directions to alleviate stress regardless of the horizontal and vertical directions.

In an example embodiment, the shape and density of the second nanoposts NP2 on the peripheral region PP may be provided uniformly regardless of locations thereof. However, example embodiments are not limited thereto, and the shape and density of the second nanoposts NP2 may be provided to vary depending on locations thereof in consideration of the degree of thermal stress and pattern of cracking. For example, the number of second nanoposts NP2 per unit area may increase in a direction toward the pixel array region AR and/or the pad region PR.

In an example embodiment, the second nanoposts NP2 for alleviating thermal stress caused by thermal expansion may also be provided on the pad region PR.

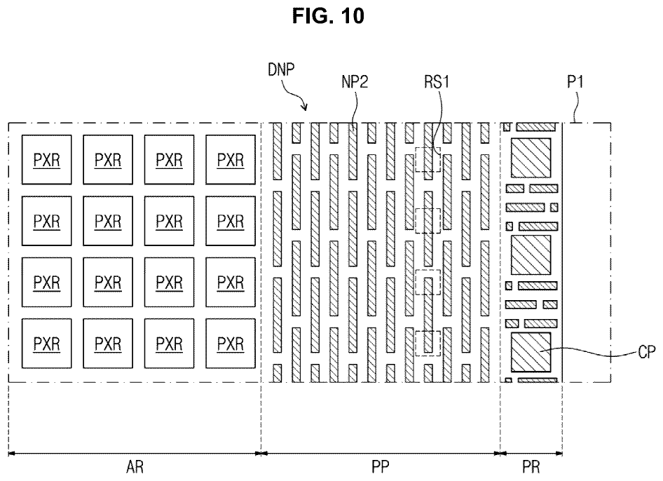

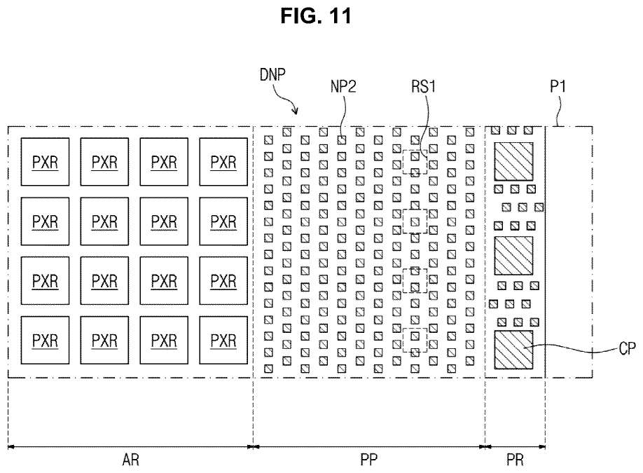

FIGS. 10 and 11 are plan views illustrating additional locations of the second nanopost in some example embodiments, and illustrate regions corresponding to portion P1 of FIG. 3A.

Referring to FIGS. 10 and 11, the second nanoposts NP2 may also be provided on a pad region PR. The second nanoposts NP2 may be disposed between two adjacent connection pads CP. In an example embodiment, the second nanoposts NP2 do not need to be provided for every gap between connection pads CP, and may also be disposed at locations at which cracking occurs frequently.

In an example embodiment, the second nanoposts NP2 disposed on the pad region PR may be provided with substantially the same shape and the same density as the second nanoposts NP2 disposed on the peripheral region PP.

In an example embodiment, as illustrated in FIG. 10, an extending direction of the second nanoposts NP2 disposed on the pad region PR may be substantially perpendicular to an extending direction of the second nanoposts NP2 disposed on the peripheral region PP. Alternatively, the extending direction of the second nanoposts NP2 disposed on the pad region PR may intersect the extending direction of the second nanoposts NP2 disposed on the peripheral region PP at an angle that is neither parallel nor perpendicular.

In an example embodiment, the second nanoposts NP2 may be disposed to be different from the above-described arrangement depending on locations thereof on the peripheral region PP. For example, the second nanoposts NP2 may be disposed in various ways in a vertex portion and an edge (side) portion of the peripheral region PP.

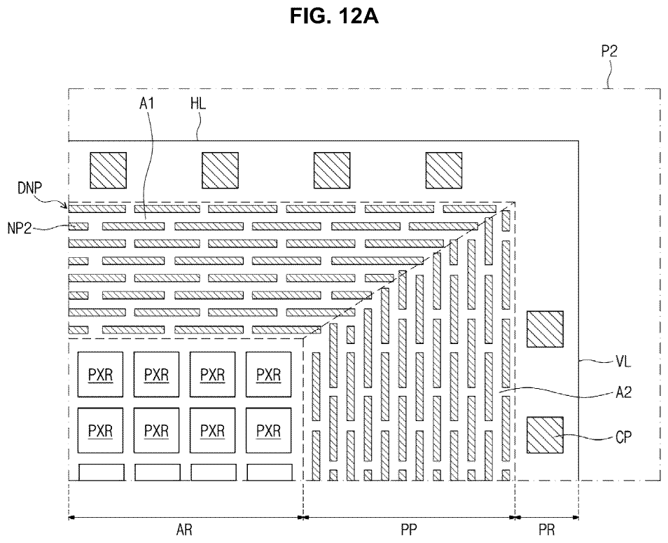

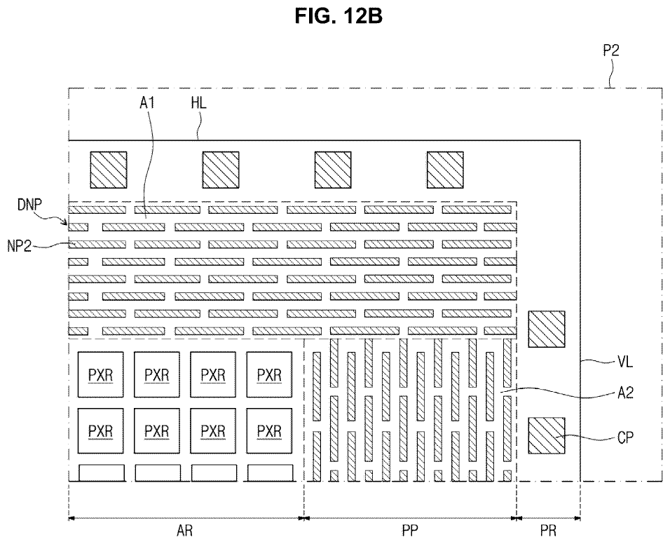

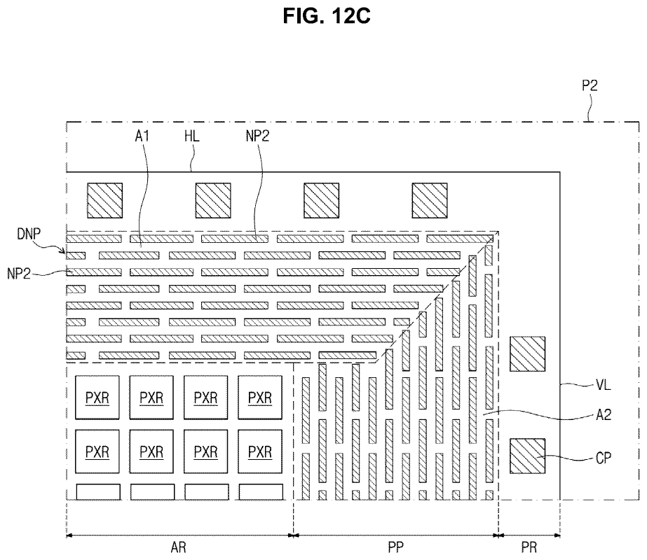

FIGS. 12A to 12C are enlarged plan views of portion P2 of FIG. 3A.

Referring to FIGS. 12A to 12C, in plan view, the second nanoposts NP2 in the peripheral region PP corresponding to a vertex and an edge of the image sensor may have different arrangements depending on locations thereof. For example, as illustrated in FIG. 12A, at a vertex of the image sensor at which a horizontal side HL and a vertical side VL intersect each other, the second nanoposts NP2 may be disposed to extend in different directions in the peripheral region PP disposed on the horizontal side HL and the peripheral region PP disposed on the vertical side VL.

In an example embodiment, a peripheral region PP in which the second nanoposts NP2 extending in a certain direction corresponding to the horizontal side HL are disposed will be referred to as a first peripheral region A1 and a peripheral region PP in which the second nanoposts NP2 are arranged, extending in a direction different from the first peripheral region A1, corresponding to the vertical side VL will be referred to as a second peripheral region A2. The second nanoposts NP2 on the first peripheral region A1 may horizontally extend in the extending direction of the horizontal side HL, and the second nanoposts NP2 on the second peripheral region A2 may vertically extend in the extending direction of the vertical side VL.

In an example embodiment, a boundary between the first peripheral region A1 and the second peripheral region A2 may have various aspects, and the arrangement of the second nanoposts NP2 may vary depending on the aspects.

Referring to FIG. 12A, a boundary between the first peripheral region A1 and the second peripheral region A2 may be set as a straight line connecting a vertex of the pixel array region AR and a vertex of the peripheral region PP. The second nanoposts NP2 may be disposed in a staggered manner with respect to the boundary between the first peripheral region A1 and the second peripheral region A2.

Referring to FIG. 12B, a boundary between the first peripheral region A1 and the second peripheral region A2 may be set as a straight line extending, parallel to a horizontal side HL, from a vertex of the pixel array region AR to a vertical side VL of the peripheral region PP. Alternatively, the boundary between the first peripheral region A1 and the second peripheral region A2 may be set as a straight line extending, parallel to the vertical side VL, from the vertex of the pixel array region AR to the horizontal side HL of the peripheral region PP. In the first peripheral region A1, the second nanoposts NP2 may horizontally extend in an extending direction of the horizontal side HL. In the second peripheral region A2, the second nanoposts NP2 may vertically extend in an extending direction of the vertical side VL.

Referring to FIG. 12C, a boundary between the first peripheral region A1 and the second peripheral region A2 may be set as a straight line extending, parallel to the horizontal side HL, from a vertex of the pixel array region AR to a specific point in the peripheral region PP, and a straight line connecting the specific point to a vertex of the peripheral region PP. Accordingly, the second nanoposts NP2 may horizontally extend in the extending direction of the horizontal side HL the specific point on the first peripheral region A1, and the second nanoposts NP2 on the first peripheral region A1, and the second nanoposts NP2 on the first peripheral region A1 and the second nanoposts NP2 on the second peripheral region A2 may be disposed to be staggered in a portion adjacent to the straight line connecting the specific point to the vertex of the peripheral region PP.

In an example embodiment, the boundary between the first peripheral region A1 and the second peripheral region A2 is not limited thereto and may be set to be different from the above-described shape.

In an example embodiment, the nanostructure layer NS may be provided in a multilayer structure.

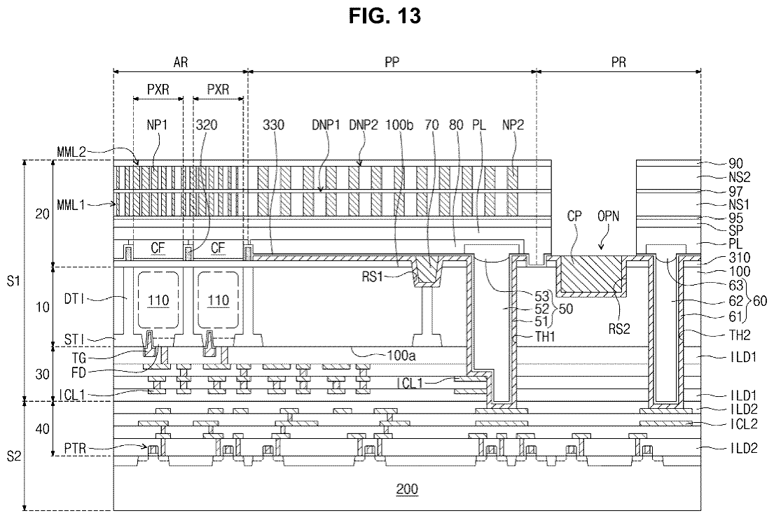

FIG. 13 is a cross-sectional view of an image sensor according to an example embodiment.

Referring to FIG. 13, a nanostructure layer NS may include a first nanostructure layer NS1 and a second nanostructure layer NS2 provided on the first nanostructure layer NS1, and for example, may be stacked on the first nanostructure layer NS1.

The first nanostructure layer NS1 may include a first metamicrolens MML1 on a pixel array region AR and a first dummy nanopattern DNP1 on a peripheral region PP. The first metamicrolens MML1 and the first dummy nanopattern DNP1 may include a first nanopost NP1 and a second nanopost NP2, respectively.

The second nanostructure layer NS2 may include a second metamicrolens MML2 on a pixel array region AR and a second dummy nanopattern DNP2 on a peripheral region PP. The second metamicrolens MML2 and the second dummy nanopattern DNP2 may include a first nanopost NP1 and a second nanopost NP2, respectively.

The first nanoposts NP1 of the first nanostructure layer NS1 may be aligned with and overlap the first nanoposts NP1 of the second nanostructure layer NS2 in a stacking direction of the first and second nanostructure layers NS1 and NS2. The first nanoposts NP1 of the first nanostructure layer NS1 may have substantially the same shape as the first nanoposts NP1 of the second nanostructure layer NS2. For example, when the first nanoposts NP1 of the first nanostructure layer NS1 have a cylindrical shape, the first nanoposts NP1 of the second nanostructure layer NS2 may also have a cylindrical shape and have the same area as the first nanoposts NP1 of the first nanostructure layer NS1.

Similarly, the second nanoposts NP2 of the first nanostructure layer NS1 may be aligned with and overlap the second nanoposts NP2 of the second nanostructure layer NS2 in a stacking direction of the first and second nanostructure layers NS1 and NS2. The second nanoposts NP2 of the first nanostructure layer NS1 may have substantially the same shape as the second nanoposts NP2 of the second nanostructure layer NS2. For example, when the second nanoposts NP2 of the first nanostructure layer NS1 have a rectangular prism shape, the second nanoposts NP2 of the second nanostructure layer NS2 may also have a rectangular prism shape and have the same area as the second nanoposts NP2 of the first nanostructure layer NS1.

An etch-stop layer may be provided between the first nanostructure layer NS1 and the second nanostructure layer NS2. For example, an etch-stop layer provided below the first nanostructure layer NS1 may be referred to as a first etch-stop layer 95, and an etch-stop layer provided between the first nanostructure layer NS1 and the second nanostructure layer NS2 may be referred to as a second etch-stop layer 97.

When the nanostructure layer NS is formed in a multilayer structure, a height of the first nanoposts NP1 or the second nanoposts NP2 may be sufficiently secured. Although it may be difficult to satisfy both the height and width of the nanoposts due to a limitation in process during the formation of the metamicrolenses MML, the height and width of the nanoposts may be adjusted to an appropriate level when the nanostructure layer NS is formed in a multilayer structure.

In an example embodiment, the nanoposts of the first nanostructure layer NS1 and the second nanostructure layer NS2 have been described as being aligned and having substantially the same shape, but example embodiments are not limited thereto. Similarly to how physical optical lenses having different shapes overlap each other to control a path of light, the first nanostructure layer NS1 and the second nanostructure layer NS2 may be designed to have different first nanoposts NP1. In addition, the first nanostructure layer NS1 and the second nanostructure layer NS2 having different first nanoposts NP1 may be stacked to efficiently control the path of light.

In addition, it will be understood that the nanostructure layer NS may be formed in a structure of two or more layers, for example, first to third nanostructure layers.

In an example embodiment, an additional functional layer, such as an anti-reflection pattern ARL, may be further formed on the nanostructure layer NS.

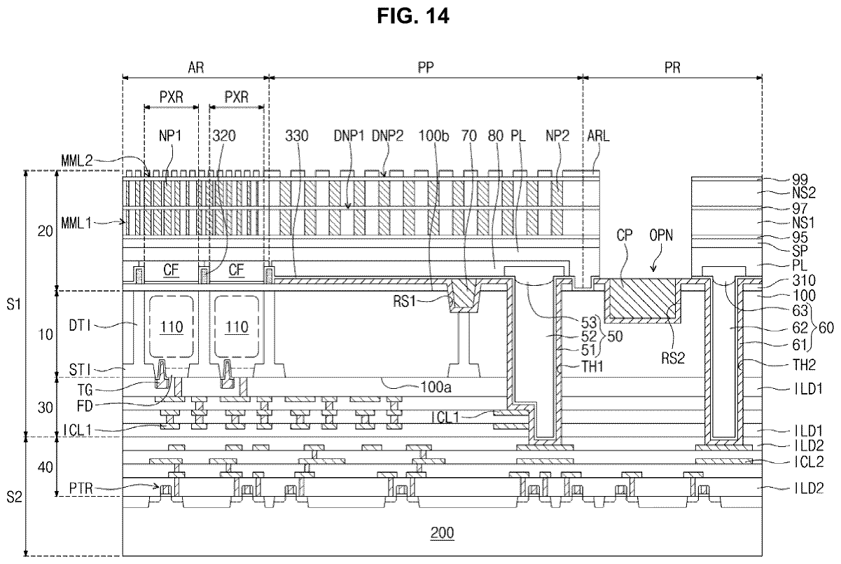

FIG. 14 is a cross-sectional view of an image sensor according to an example embodiment, illustrating the image sensor illustrated in FIG. 13 with an additional anti-reflection pattern ARL formed thereon.

Referring to FIG. 14, a third etch-stop layer 99 may be provided on the second nanostructure layer NS2, and an anti-reflection pattern ARL may be provided on the third etch-stop layer 99.

The anti-reflection pattern ARL may include protrusion patterns on the third etch-stop layer 99. The protrusion patterns of the anti-reflection pattern ARL may or may not overlap the nanoposts NP of the second nanostructure layer NS2, for example, the first and second nanoposts NP1 and NP2. For example, the protrusion patterns of the anti-reflection pattern ARL may be aligned to overlap the nanoposts NP of the second nanostructure layer NS2, for example, the first and second nanoposts NP1 and NP2. For example, the protrusion patterns may have substantially the same shape as the nanoposts of the second nanostructure layer NS2, for example, the first and second nanoposts NP1 and NP2. When the protrusion patterns of the anti-reflection pattern ARL and the nanoposts of the second nanostructure layer NS2 have the same shape, the protrusion patterns of the anti-reflection pattern ARL may be formed using an etch mask used to form the nanoposts of the second nanostructure layer NS2. an additional etch mask is not required to form the anti-reflection pattern ARL, process costs, operations and complexity may be reduced.

In an example embodiment, a portion of the nanostructure layer NS may be used as a color separation lens array.

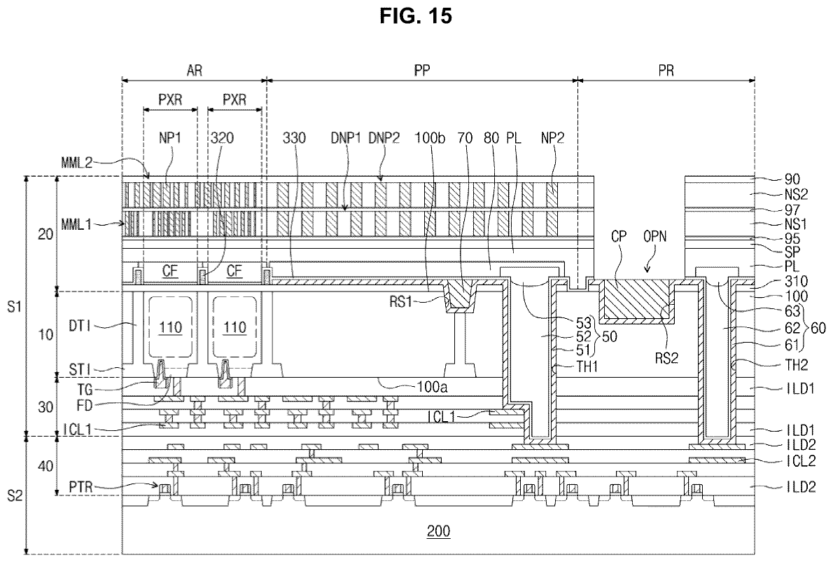

FIG. 15 is a cross-sectional view of an image sensor according to an example embodiment, in which a portion of a nanostructure layer NS is used as a color separation lens array.

Referring to FIG. 15, the nanostructure layer NS may include a first nanostructure layer NS1 and a second nanostructure layer NS2 on the first nanostructure layer NS1. For example, the second nanostructure layer NS2 may be stacked on the first nanostructure layer NS1.

In a pixel array region AR, the first nanostructure layer NS1 may include a color separation lens array and the second nanostructure layer NS2 may include a metamicrolens MML. In the peripheral region PP, the first and second nanostructure layers NS2 may include dummy nanopatterns DNP.

A color separation lens array CSLA is a component configured to collect light of a corresponding color in each pixel region PXR. The color separation lens array may include a plurality of first nanoposts NP1 that change a phase of incident light to vary depending on an incident location. At least a portion of the first nanoposts NP1 of the first nanostructure layer NS1 may not overlap at least a portion of the first nanoposts NP1 of the second nanostructure layer NS2 in a direction in which the first and second nanostructure layers NS1 and NS2 are stacked.

The color separation lens array may form different phase profiles for different wavelengths of light included in incident light to collect different wavelengths of light for each pixel region. For example, the color separation lens array may collect light of a first wavelength in one pixel region and collect light of a second wavelength in another pixel region. Because a refractive index of a material varies depending on a wavelength of interacting light, the color separation lens array may provide different phase profiles for different wavelengths of light. For example, even for the same material, a refractive index varies depending on a wavelength of light interacting with the material, and phase delay experienced by light when passing through the material also varies depending on the wavelength, so that different phase profiles may be formed for each wavelength.

The first nanostructure layer NS1 may include first nanoposts NP1 arranged according to a specific rule such that the color separation lens array has different phases of light of different wavelengths (for example, blue, green, and red wavelengths of light). The specific rule refers to parameters such as shape, size (width and height), spacing, and arrangement of the nanoposts NP. The parameters may be determined based on a phase profile to be implemented through the color separation lens array. Size, shape, spacing, and/or arrangement of the first nanoposts NP1 in each pixel region PXR may be different from the size, shape, spacing, and/or arrangement of the nanoposts NP in another region to implement different phase profiles for each pixel region PXR.

The color filters CF may be selectively omitted. In an example embodiment, the first nanostructure layer NS1 is used as a color separation lens array, so that no additional component is required to represent a color for each pixel. However, in some example embodiments, even when the first nanostructure layer NS1 represents a color, a color filter CF may not be omitted to supplement additional colors. The color separation lens array may perform color separation, and the additionally provided color filter array may supplement some errors, which may occur during color separation performed by the color separation lens array, to increase color purity.

In an example embodiment, the image sensor may be provided with a structure, different from the above-described examples.

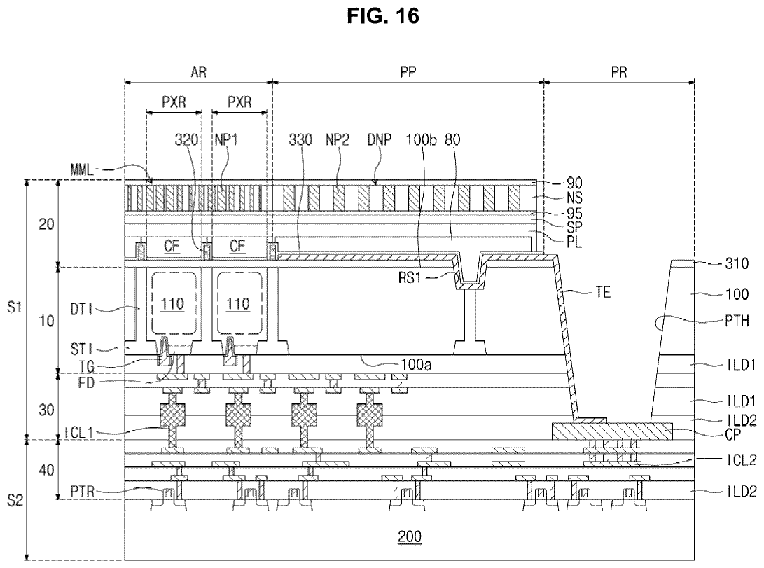

FIG. 16 is a cross-sectional view illustrating an image sensor according to an example embodiment, illustrating that a first chip and a second chip are formed to be different from those described above.

FIG. 16 is a cross-sectional view illustrating an image sensor according to some example embodiments. FIG. 16 may be a cross-sectional view corresponding to line A-A′ of FIG. 3B.

Referring to FIG. 16, a connection pad CP may be disposed within a second interconnection layer 40 of a second chip S2. For example, the connection pad CP may be disposed within the second interconnection layer 40 below a pad region PR of a first substrate 100. In plan view, the connection pad may overlap the pad region PR. In an example embodiment, a side surface and an upper surface of the connection pad CP may be covered with an uppermost second interlayer dielectric among second interlayer dielectrics ILD2. A pad through-hole PTH may expose the upper surface of the connection pad CP through the first substrate 100, a first interconnection layer 30, and a portion of the second interconnection layer 40 (for example, the uppermost second interlayer dielectric ILD2) in the pad region PR.

A through-electrode TE may be disposed within the pad through-hole PTH. In an example embodiment, the through-electrode TE may be in contact with at least a portion of the exposed upper surface of the connection pad CP. The through-electrode TE may extend upwardly of at least a portion of an inner side surface of the pad through-hole PTH. In addition, the through-electrode TE may extend along the second surface 100b of the first substrate 100. Thus, the through-electrode TE may electrically connect the connection pad CP to at least one of various terminals adjacent to the second surface 100b of the first substrate 100. For example, the through-electrode TE may extend upwardly of an inner surface of the first recess RS1 and be connected to a filling conductive pattern of a deep trench isolation pattern DTI.

In some example embodiments, the first chip S1 may further include first bonding pads BP1 provided in a lowermost first interlayer dielectric among first interlayer dielectrics ILD1, and the second chip S2 may further include second bonding pads BP2 provided in the uppermost second interlayer dielectric among the second interlayer dielectrics ILD2. The first bonding pads BP1 may be bonded to the second bonding pads BP2, respectively. In an example embodiment, the first and second bonding pads BP1 and BP2 may be formed of copper, and the first and second bonding pads BP1 and BP2 may be bonded to each other by a copper-to-copper bonding method. An interface between the first and second bonding pads BP1 and BP2 bonded to each other may not be apparent.

As illustrated, the second recess RS2 and the first and second connection structures 50 and 60 of FIG. 4 may be omitted. However, example embodiments are not limited thereto. In some example embodiments, at least one of the first and second connection structures 50 and 60 may be applied to the image sensor. For example, the first and second chips S1 and S2 may be electrically connected to each other through at least one of the first and second connection structures 50 and 60 and/or the first and second bonding pads BP1 and BP2.

The image sensors having the above-described structure have been described as examples, and various modifications may be made without departing from the concept of the present disclosure. For example, the above-described examples may be combined in various forms, except for situations in which they are incompatible. The image sensors having the above-described structure may alleviate or buffer stress, applied to the peripheral region PP and the region adjacent to the peripheral region PP, to reduce or prevent defects such as cracking that may occur in the image sensor.

Hereinafter, a method of manufacturing the image sensor illustrated in FIG. 14 will be described as an example to avoid duplication of the description. However, it will be understood that a method of manufacturing the image sensor according to an example embodiment may be modified in various forms within the concept of the present disclosure.

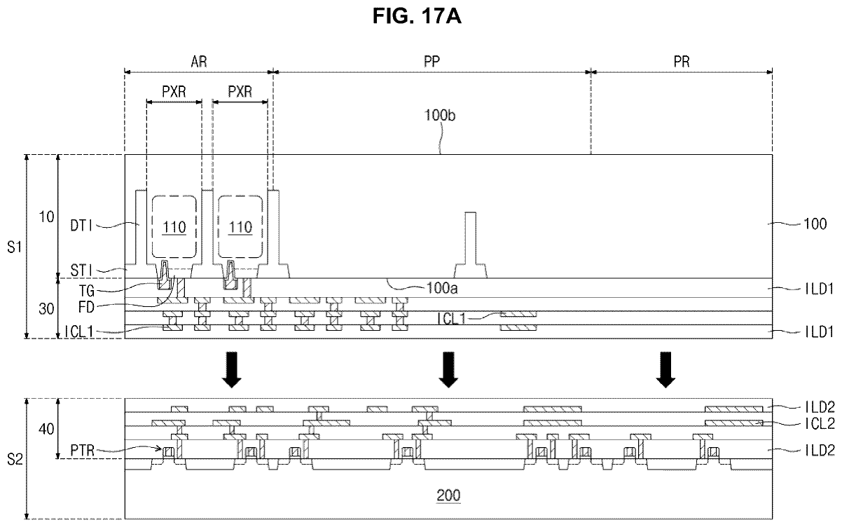

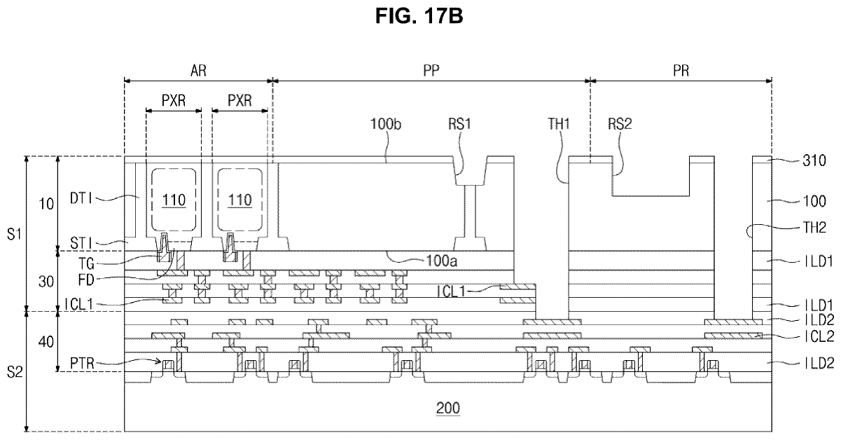

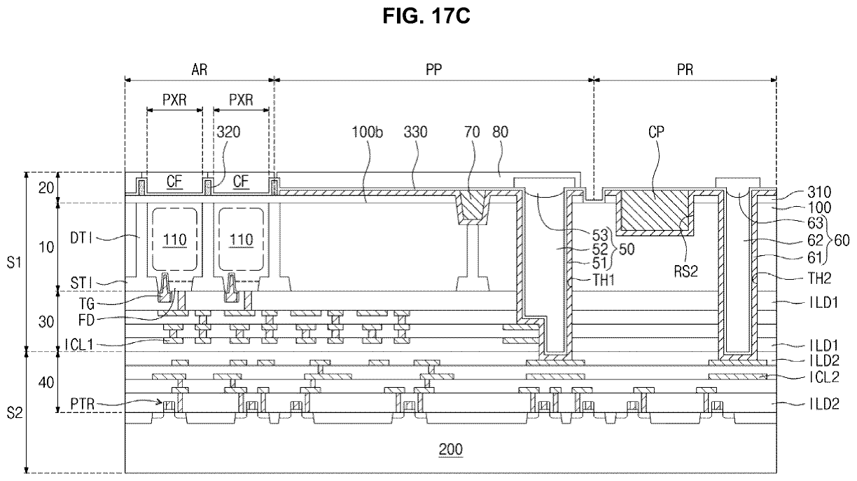

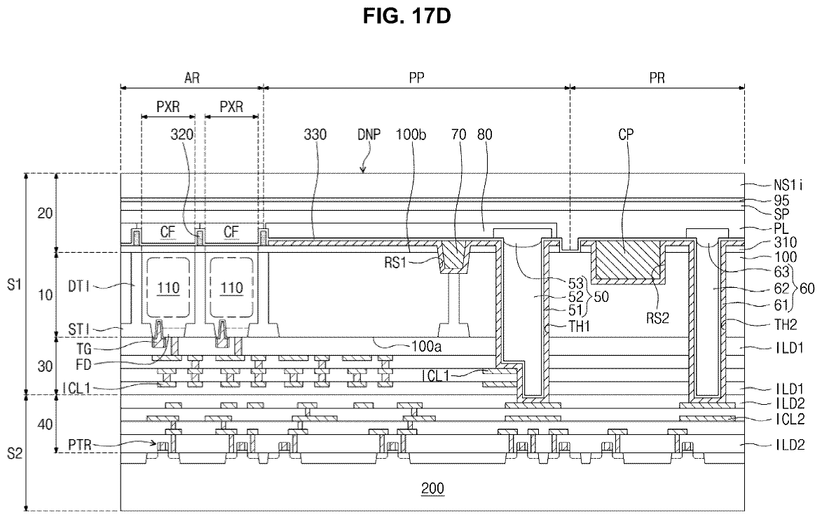

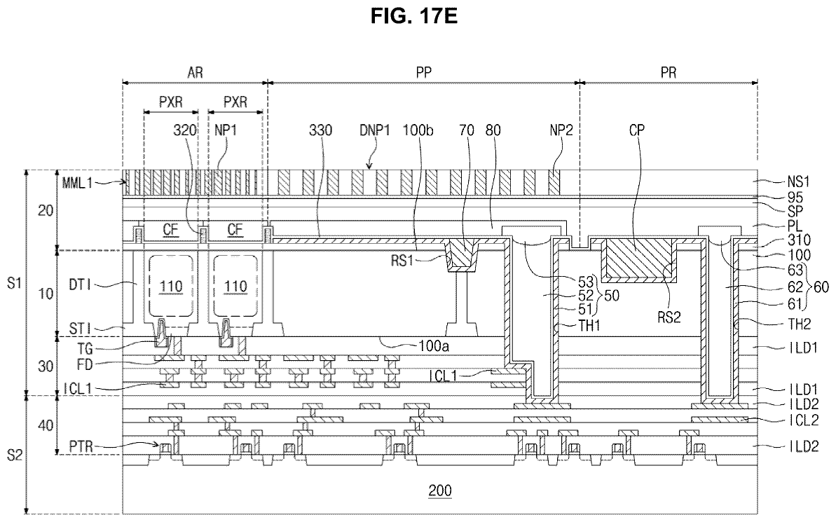

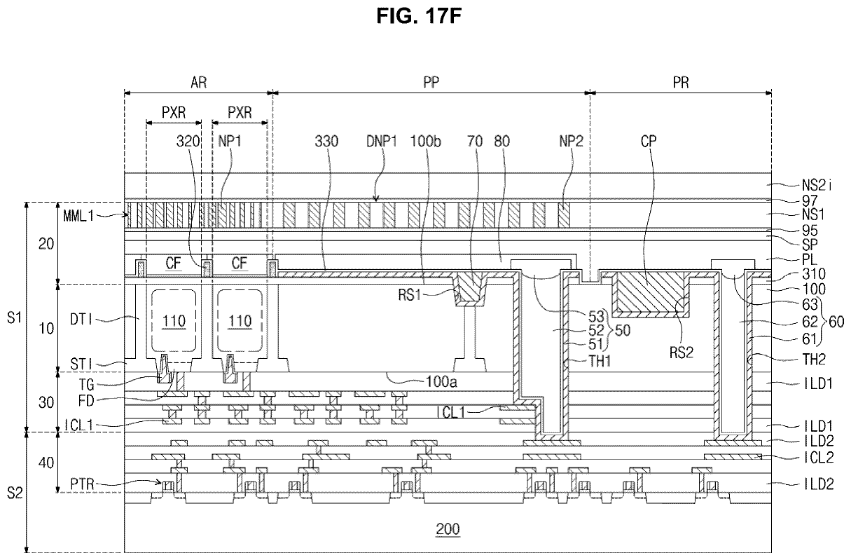

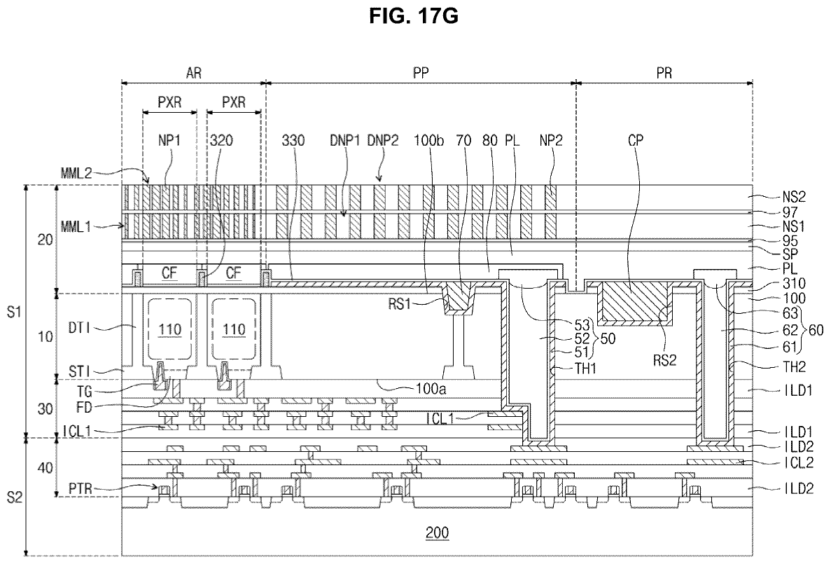

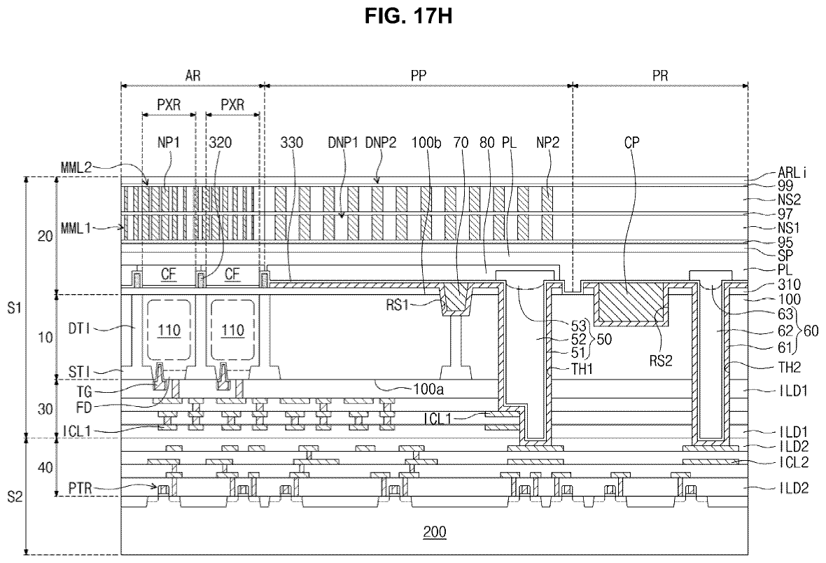

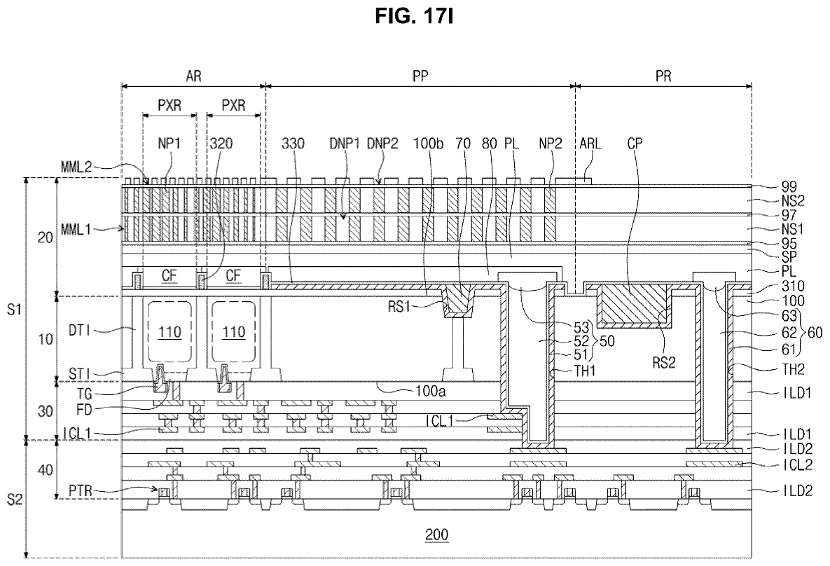

FIGS. 17A to 17I are cross-sectional views, sequentially illustrating a method of manufacturing an image sensor according to an example embodiment.

Referring to FIG. 17A, a portion of a first chip S1 and a second chip S2 may be prepared, and the first chip S1 may be flipped to be disposed on the second chip S2 and then bonded thereto.

To form the first chip S1, the first substrate 100 may be prepared and some components of a pixel may be formed on the first surface 100a of the first substrate 100. In the present operation, a first interconnection layer 30 may be formed on the first surface 100a of the first substrate 100. The second chip S2 may be prepared separately from the first chip S1. The second chip S2 may be formed by preparing a second substrate 200 and forming peripheral transistors PTR and a second interconnection layer 40 on the second substrate 200.

Referring to FIG. 17B, after the first chip S1 and the second chip S2 are bonded, a portion of the first substrate 100 on a side of a rear surface, for example, a second surface 100b of the first chip S1 may be removed. A portion of the first substrate 100 may be removed through a chemical mechanical polishing (CMP) process. The CMP process may be performed until a deep trench isolation pattern DTI is exposed. Then, a transmission insulating layer 310 may be formed on the second surface 100b of the first substrate 100, and first and second recesses RS1 and RS2, first and second through-holes TH1 and TH2, or the like, may be formed.

Referring to FIG. 17C, a grid 320, connection structures 50 and 60, a connection pad CP, a color filter CF, a protective layer 330, a color filter CF, and a filtering pattern 80 may be formed on the first substrate 100.

Referring to FIG. 17D, a planarization layer PL, a spacer SP, a first etch-stop layer 95, and a first initial nanostructure layer NSli may be sequentially formed on the first substrate 100.

The planarization layer PL may be applied using an organic polymer and then cured, and the spacer SP, the first etch-stop layer 95, and the first initial nanostructure layer NSli may each be deposited. The first initial nanostructure layer NSli may be formed of a material having a relatively low refractive index.

Referring to FIG. 17E, the first initial nanostructure layer NSli may be patterned using a photolithography process and an etching process to form a first nanostructure layer pattern, and then a first nanorefractive pattern material having a relatively high refractive index may be deposited to form a first nanostructure layer NS1. For example, a first initial nanostructure layer NSli may be formed of a low-refractive material on the first substrate 100, and a low-refractive material layer may then be etched to form a first nanostructure layer pattern having a plurality of holes and a high-refractive material may fill the holes. The first etch-stop layer 95 may prevent a spacer SP below the first etch-stop layer 95 from being etched during etching of the low-refractive material. The plurality of holes may be formed to correspond to regions in which first and second nanoposts NP1 and NP2 are to be formed. A material of a first nanorefractive pattern (for example, the high-refractive material) may be deposited in the holes of the first nanostructure layer pattern to form first nanoposts NP1 and second nanoposts NP2. An upper surface of the first nanostructure layer NS1 may be polished by CMP.

As described above, the first nanostructure layer NS1 may include metamicrolenses MML and a dummy nanopattern DNP. In an example embodiment, the metamicrolenses MML on a pixel array region AR and the dummy nanopattern DNP on a peripheral region PP may be formed individually using separate photolithography processes. However, the metamicrolenses MML and the dummy nanopattern DNP may be formed using a single mask in a single photolithography process, which may simplify the manufacturing process, and reduce complexity and costs.

Referring to FIG. 17F, a second etch-stop layer 97 may be formed on the first nanostructure layer NS1, and a second initial nanostructure layer NS2i may be formed on the second etch-stop layer 97. The second initial nanostructure layer NS2i may be formed of a second nanorefractive pattern material having a relatively low refractive index.

Referring to FIG. 17G, the second initial nanostructure layer NS2i may be patterned using a photolithography process and an etching process to form a second nanostructure layer pattern, and a first nanorefractive pattern material having a relatively high refractive index may then be deposited to form a second nanostructure layer NS2. The first nanorefractive pattern material may be deposited in the holes of the second nanostructure layer pattern to the first nanoposts NP1 and the second nanoposts NP2. An upper surface of the second nanostructure layer NS2 may be polished by CMP.

Referring to FIG. 17H, a third etch-stop layer 99 and an initial anti-reflective layer ARLi may be formed on a substrate on which the second nanostructure layer NS2 is formed. The initial anti-reflective layer ARLi may be formed of a material having a relatively low refractive index.

Referring to FIG. 17I, the initial anti-reflective layer ARLi may be etched through a photolithography process to form an anti-reflective pattern ARL.

Returning to FIG. 14, the third etch-stop layer 99, the second nanostructure layer NS2, the second etch-stop layer 97, the first nanostructure layer NS1, the first etch-stop layer 95, the spacer SP, and the planarization layer PL may be patterned using a photolithography process and an etching process to form an opening OPN. An upper surface of the connection pad CP may be exposed by the opening OPN.

As set forth above, example embodiments provide an image sensor with improved structural integrity due to significantly reduced cracking occurrence caused by stress, as well as a method of manufacturing the image sensor, by providing a structure that may alleviate or buffer a stress difference in the image sensor.

While example embodiments have been shown and described above, it will be apparent to those skilled in the art that modifications and variations could be made without departing from the scope of the present inventive concept as defined by the appended claims.

What is claimed is:

1. An image sensor comprising:
photodiodes provided in a pixel array region;
a peripheral region provided on at least one side of the pixel array region; and
a nanostructure layer provided on the pixel array region and the peripheral region,
wherein the nanostructure layer comprises:
metamicrolenses on the pixel array region, wherein the metamicrolenses are configured to collect light incident on the pixel array region; and
a dummy nanopattern on the peripheral region.

2. The image sensor of claim 1, wherein each of the metamicrolenses and the dummy nanopattern comprises a first nanorefractive pattern having a first refractive index and a second nanorefractive pattern having a second refractive index,
wherein the first refractive index is different than the second refractive index, and
wherein the first nanorefractive pattern comprises nanoposts.

3. The image sensor of claim 2, wherein the nanostructure layer comprises a first nanostructure layer and a second nanostructure layer provided on the first nanostructure layer.

4. The image sensor of claim 3, wherein the first nanostructure layer comprises a color separation lens array.

5. The image sensor of claim 3, wherein the nanoposts comprise first layer nanoposts in the first nanostructure layer and second layer nanoposts in the second nanostructure layer, and
wherein the first layer nanoposts overlap the second layer nanoposts, in plan view.

6. The image sensor of claim 3, wherein the nanoposts comprise first layer nanoposts in the first nanostructure layer and second layer nanoposts in the second nanostructure layer, and
wherein at least one of the first layer nanoposts does not overlap the second layer nanoposts, in plan view.

7. The image sensor of claim 2, further comprising color filters provided on the pixel array region.

8. The image sensor of claim 2, wherein each of the metamicrolenses comprises a plurality of first nanoposts, and
wherein the dummy nanopattern comprises a plurality of second nanoposts.

9. The image sensor of claim 8, wherein the plurality of second nanoposts comprises bar shaped second nanoposts extending in a first direction, in plan view.

10. The image sensor of claim 9, wherein the first direction is parallel to a boundary between the pixel array region and the peripheral region.

11. The image sensor of claim 8, wherein each of the plurality of second nanoposts has a polygonal prism shape, a cylindrical shape, or an elliptical cylinder shape.

12. The image sensor of claim 8, wherein a density of the plurality of second nanoposts per unit area in the peripheral region is 80% to 120% of a density of the plurality of first nanoposts per unit area in the pixel array region, in plan view.

13. The image sensor of claim 8, further comprising:
a pad region provided on one side of the peripheral region; and
a connection pad provided on the pad region,
wherein the connection pad provides an electrical connection to an external device.

14. The image sensor of claim 13, comprising:
a first chip; and
a second chip provided below the first chip and bonded to the first chip,
wherein the connection pad is included in the first chip.

15. The image sensor of claim 13, wherein the plurality of second nanoposts are provided in the pad region.

16. The image sensor of claim 15, wherein a first group of the plurality of second nanoposts on the peripheral region have a bar shape extending in a first direction, and a second group of the plurality of second nanoposts provided on the pad region have a bar shape extending in a second direction different from the first direction.

17. The image sensor of claim 13, comprising:
a first chip; and
a second chip provided below the first chip and bonded to the first chip,
wherein the connection pad is included in the second chip.

18. The image sensor of claim 17, wherein the first chip and the second chip are bonded to each other using a copper-to-copper bonding method.

19. A method of manufacturing an image sensor, the method comprising:
providing a substrate with a pixel array region and a peripheral region;
forming an etch-stop layer on the pixel array region and the peripheral region;
forming an initial nanostructure layer comprising a material having a first refractive index on the pixel array region and the peripheral region;
patterning the initial nanostructure layer to form a plurality of holes;
depositing a material having a second refractive index, different from the first refractive index, in the plurality of holes to form nanoposts,
forming metamicrolenses using the nanoposts on the pixel array region; and
forming a dummy nanopattern using the nanoposts on the peripheral region.

20. The method of claim 19, wherein the forming the metamicrolenses on the pixel array region and the forming the dummy nanopattern on the peripheral region are performed using a single mask.
